(19) United States
(12) Patent Application Publication
(10) Pub. No.: US 2025/0089217 A1
(43) Pub. Date: Mar. 13, 2025

(54) HEAT SINK

(71) Applicant: FURUKAWA ELECTRIC CO., LTD., Tokyo (JP)

(72) Inventor: Yosuke WATANABE, Tokyo (JP)

(73) Assignee: FURUKAWA ELECTRIC CO., LTD., Tokyo (JP)

(21) Appl. No.: 18/956,496

(22) Filed: Nov. 22, 2024

Related U.S. Application Data
(63) Continuation of application No. PCT/JP2022/041834, filed on Nov. 10, 2022.

(30) Foreign Application Priority Data
May 25, 2022 (JP) 2022-085167

(51) Int. Cl. H05K 7/20

(52) U.S. Cl. CPC H05K 7/2039

(57) ABSTRACT

The heat sink including a base plate and a plurality of plate-like radiating fins, wherein the plate-like radiating fins have a fin base portion that extends from one end to another end of the plate-like radiating fin, and a twisted portion that is provided in a height direction of the plate-like radiating fin from the fin base portion, and inclines in a main front surface direction of the base plate, and the twisted portion has a planar region defined by a twist start portion that linearly stretches from the fin base portion, one end portion that is at least a part of the one end facing the twist start portion and inclines at an angle θ1, and a fin tip portion that is at least a part of a fin tip facing the fin base portion, and inclines at an angle θ2 with respect to the fin base portion.

### CROSS REFERENCE TO RELATED APPLICATIONS

The present application is a continuation application of International Patent Application No. PCT/JP2022/041834 filed on Nov. 10, 2022, which claims the benefit of Japanese Patent Application No. 2022-085167, filed on May 25, 2022. The contents of these applications are incorporated herein by reference in their entirety.

### BACKGROUND

### Technical Field

The present disclosure relates to a heat sink including a radiating fin that cools a heat-generating element such as an electronic component.

### Background

Heat-generating elements such as electronic components are being installed in electronic devices at high densities due to enhancement in functionality of the electronic devices. A heat sink may be used as a unit configured to cool heat-generating elements such as electronic components. Forced air cooling by a blower fan and the like is performed in the heat sink. The cooling performance of the heat sink may be improved by supplying cooling air to the heat sink.

The heat generation amount of heat-generating elements such as electronic components has been increasing in recent years due to the enhancement in functionality of electronic devices, and it is becoming increasingly important to improve the cooling performance of the heat sink. Improvement of the fin efficiency of radiating fins is being proposed in order to improve the cooling performance of the heat sink. Thus, a heat sink as follows has been proposed (Japanese Patent Laid-Open No. 2015-164166). In the heat sink, inclination angles of heat dissipation surfaces with respect to one surface portion of a base plate differ between radiating fin groups adjacent to each other in a depth length direction, and end surfaces of the adjacent radiating fin groups intersect each other on a supporting substrate when seen from one side of the depth length direction of the heat sink.

In the heat sink of Japanese Patent Laid-Open No. 2015-164166, the radiating fins are disposed in an offset manner. Therefore, when the cooling air flows into the radiating fin group on the rear side, the cooling air breaks a thermal boundary layer, which has gradually grown in a process of the cooling air passing through the radiating fin group on the front side, by becoming turbulence, and mixes cooling air of low temperature and cooling air of high temperature together. As a result, the cooling air of low temperature is easily caused to contact front surfaces of the radiating fins, and the fin efficiency of the radiating fins is improved.

However, in the heat sink of Japanese Patent Laid-Open No. 2015-164166, the radiating fins are disposed in an offset manner. Therefore, although turbulence is generated in the cooling air when the cooling air passes through the radiating fin groups of which inclination angles of the heat dissipation surfaces differ, the pressure loss of the cooling air increases, the flow of the cooling air is dispersed, and the wind speed of the cooling air between the radiating fins decreases. As a result, in the heat sink of Japanese Patent Laid-Open No. 2015-164166, there is a tendency that heat dissipation characteristics are not sufficiently improved.

The fin efficiency of the radiating fins is defined by Fin Efficiency=(Average Temperature of Radiating Fin−Ambient Temperature)/(Temperature of Fin Base Portion−Ambient Temperature). Therefore, in order to improve the fin efficiency of the radiating fin, the temperature of the fin base portion of the radiating fin that is the closest to the heat-generating element and that becomes the highest in temperature needs approach the average temperature of the radiating fin as much as possible. However, in the heat sink of Japanese Patent Laid-Open No. 2015-164166, the flow rate of the cooling air at the fin base portion that becomes the highest in temperature in the radiating fin tends to be less than the flow rate of the cooling air at the fin tip that is the farthest from the heat-generating element and that becomes the lowest in temperature due to the presence of the base plate, and hence the fin base portion easily becomes high in temperature. Therefore, in the heat sink of Japanese Patent Laid-Open No. 2015-164166, the temperature of the fin base portion of the radiating fin becomes extremely higher than the average temperature of the radiating fin, and excellent fin efficiency still cannot be obtained.

In electronic devices, heat-generating elements such as electronic components are installed at high densities, and the installable volume for the heat sink is limited. Therefore, it is difficult to improve the heat dissipation characteristics of the heat sink by increasing the surface area of each of the radiating fins. When the number of installations of the radiating fins is increased instead of increasing the surface area of each of the radiating fins, the pressure loss of the cooling air increases, and the wind speed of the cooling air between the radiating fins decreases. Even when the wind flow rate of the cooling air is increased in order to make up for the increase of the pressure loss of the cooling air, the difference between the temperature of the fin base portion of the radiating fin and the average temperature of the radiating fin increases, and excellent fin efficiency still cannot be obtained. In addition, when the wind flow rate of the cooling air is increased, power consumption increases, a burden on the environment increases, and noise generation is caused.

### SUMMARY

The present disclosure is related to providing a heat sink in which excellent fin efficiency is obtainable by reducing a difference between a temperature of a fin base portion and an average temperature of a radiating fin as a result of a flow rate of cooling air at a fin base portion becoming faster than a flow rate of cooling air at a fin tip by a flow of the cooling air being guided to the fin base portion of the radiating fin, and increase of pressure loss of the cooling air is preventable as a result of the cooling air also flowing easily to a fin tip and a vicinity of the fin tip.

A gist of a configuration of the present disclosure is as follows.

[1] A heat sink including a base plate thermally connected to a heat-generating element, and a plurality of plate-like radiating fins erected on a main front surface of the base plate and thermally connected to the base plate,
wherein the plate-like radiating fins each having a width direction and a height direction each have
   a fin base portion that extends from one end to another end in the width direction of the plate-like radiating fin along the main front surface of the base plate, and
   a twisted portion that is continuously provided in the height direction of the plate-like radiating fin from the fin base portion, and inclines in a main front surface direction of the base plate, and
the twisted portion has a planar region defined by
   a twist start portion that linearly stretches from the fin base portion along the height direction of the plate-like radiating fin,
   one end portion that is at least a part of the one end facing the twist start portion, and inclines at an angle θ1 in the main front surface direction of the base plate with respect to the twist start portion, and
   a fin tip portion that is at least a part of a fin tip facing the fin base portion, and inclines at an angle θ2 along an extending direction of the main front surface of the base plate to the one end portion from the twist start portion, with respect to a stretching direction of the fin base portion.

[2] The heat sink according to [1], wherein the twist start portion is positioned at the other end.

[3] The heat sink according to [1], wherein the twist start portion is positioned between the one end and the other end.

[4] The heat sink according to any one of [1] to [3], wherein as a result of a plurality of the plate-like radiating fins being disposed along a width direction of the fin base portion, and an end portion in the width direction of the fin base portion of the plate-like radiating fin being connected to an end portion in a width direction of the fin base portion of another adjacent one of the plate-like radiating fins, the plurality of the plate-like radiating fins are integrated.

[5] The heat sink according to [4], wherein a space between the twisted portion of the plate-like radiating fin and the twisted portion of the other adjacent plate-like radiating fin is a gap.

[6] The heat sink according to [4], wherein the twisted portion of the plate-like radiating fin is connected to the twisted portion of the other adjacent plate-like radiating fin via a joining portion.

[7] The heat sink according to [3], wherein the twisted portion has
a first planar region defined by
   the one end portion that is at least a part of the one end facing the twist start portion, and inclines at an angle θ1 in the main front surface direction of the base plate with respect to the twist start portion, and a first fin tip portion that is a part of the fin tip facing the fin base portion, and inclines at an angle θ2 along the extending direction of the main front surface of the base plate to the one end portion from the twist start portion, with respect to the stretching direction of the fin base portion, and
a second planar region defined by
   another end portion that is at least a part of the other end facing the twist start portion, and inclines at an angle θ3 in the main front surface direction of the base plate with respect to the twist start portion, and
   a second fin tip portion that is a part of the fin tip facing the fin base portion, and inclines at an angle θ4 along the extending direction of the main front surface of the base plate to the other end portion from the twist start portion with respect to the stretching direction of the fin base portion.

[8] The heat sink according to [7], wherein an inclining direction of the angle θ1with respect to the twist start portion is opposite to an inclining direction of the angle θ3 with respect to the twist start portion, and an inclining direction of the angle θ2 with respect to the stretching direction of the fin base portion is opposite to an inclining direction of the angle θ4 with respect to the stretching direction of the fin base portion.

[9] The heat sink according to [7], wherein an inclining direction of the angle θ1 with respect to the twist start portion is the same as an inclining direction of the angle θ3 with respect to the twist start portion, and an inclining direction of the angle θ2 with respect to the stretching direction of the fin base portion is the same as an inclining direction of the angle θ4 with respect to the stretching direction of the fin base portion.

[10] The heat sink according to any one of [1] to [3], wherein the fin base portion has a planar surface portion extending from the one end to the other end in the width direction of the plate-like radiating fin.

[11] The heat sink according to any one of [1] to [3], wherein a top surface portion having a planar surface shape further extends from the fin tip.

[12] The heat sink according to [11], wherein a top surface is formed on a radiating fin group formed by the plurality of plate-like radiating fins as a result of the top surface portion abutting against the fin tip of another adjacent one of the plate-like radiating fins.

[13] The heat sink according to any one of [1] to [3], wherein a bottom surface portion having a planar surface shape further extends from a bottom portion of the fin base portion along the extending direction of the main front surface of the base plate.

[14] The heat sink according to [13], wherein a bottom surface is formed on a radiating fin group formed by the plurality of plate-like radiating fins as a result of the bottom surface portion abutting against the fin base portion of another adjacent one of the plate-like radiating fins.

[15] The heat sink according to any one of [1] to [3], wherein a height of the fin base portion with respect to a height of the plate-like radiating fin is 5% or more and 30% or less.

[16] The heat sink according to any one of [1] to [3], wherein the angle θ1 is 2.0 degrees or more and 20 degrees or less.

[17] The heat sink according to [7], wherein the angle θ1 is 2.0 degrees or more and 20 degrees or less, and the angle θ3 is 2.0 degrees or more and 20 degrees or less.

[18] The heat sink according to any one of [1] to [3], wherein the angle θ2 is 2.0 degrees or more and 20 degrees or less.

[19] The heat sink according to [7], wherein the angle θ2 is 2.0 degrees or more and 20 degrees or less, and the angle θ4 is 2.0 degrees or more and 20 degrees or less.

[20] The heat sink according to any one of [1] to [3], wherein cooling air is supplied from the one end toward the other end, in the width direction of the plate-like radiating fin.

According to an aspect of the heat sink of the present disclosure, the plate-like radiating fins each have the fin base portion that extends from the one end to the other end in the width direction of the plate-like radiating fin along the main front surface of the base plate, and the twisted portion that is continuously provided in the height direction of the plate-like radiating fin from the fin base portion, and inclines in the main front surface direction of the base plate, and the twisted portion has the planar region defined by the twist start portion that linearly stretches from the fin base portion along the height direction of the plate-like radiating fin, the one end portion that is at least a part of the one end facing the twist start portion and inclines at the angle θ1 in the main front surface direction of the base plate with respect to the twist start portion, and the fin tip portion that is at least a part of the fin tip facing the fin base portion and inclines at the angle θ2 along the extending direction of the main front surface of the base plate to the one end portion from the twist start portion, with respect to the stretching direction of the fin base portion. As a result, the flow of the cooling air is guided to the fin base portion of the plate-like radiating fin by the twisted portion, and the flow rate of the cooling air at the fin base portion becomes faster than the flow rate of the cooling air at the fin tip. Therefore, the difference between the temperature of the fin base portion and the average temperature of the radiating fin can be reduced, and excellent fin efficiency can be obtained. According to an aspect of the heat sink of the present disclosure, the planar region of the twisted portion extends from the twist start portion to the one end portion of the plate-like radiating fin, and from the border with the fin base portion to the fin tip portion. As a result, the cooling air also flows easily to the fin tip and the vicinity of the fin tip while the flow of the cooling air is guided to the fin base portion of the plate-like radiating fin, and hence, the increase of the pressure loss of the cooling air can be prevented. Therefore, the heat sink of the present disclosure can exhibit excellent heat dissipation characteristics.

According to an aspect of the heat sink of the present disclosure, the plate-like radiating fin has the twisted portion described above. As a result, even when the plate-like radiating fins are not disposed in an offset manner, the cooling air is smoothly sent to between the adjacent plate-like radiating fins that are parallelly disposed. Therefore, turbulence can be generated in the cooling air and can contribute to improvement of the heat dissipation efficiency.

According to an aspect of the heat sink of the present disclosure, the twist start portion is positioned in at least a part of the other end. As a result, the twisted portion extends from the one end to the other end in the width direction of the plate-like radiating fin. Therefore, guide of the cooling air to the fin base portion by the twisted portion is further promoted, and the fin efficiency is further improved.

According to an aspect of the heat sink of the present disclosure, the fin base portions of the plurality of plate-like radiating fins are integrated, as a result of the plurality of plate-like radiating fins being disposed along the width direction of the fin base portion, and the end portion in the width direction of the fin base portion of the plate-like radiating fin being connected to the end portion in the width direction of the fin base portion of the other adjacent one of the plate-like radiating fins. As a result, the flow of the cooling air becomes a continuous flow at a high flow rate in the integrated fin base portions. Therefore, the difference between the temperature of the fin base portion and the average temperature of the plate-like radiating fin can be further reduced, and more excellent fin efficiency can be obtained.

According to an aspect of the heat sink of the present disclosure, the fin base portions of the plurality of plate-like radiating fins are integrated, and the space between the twisted portion of the plate-like radiating fin and the twisted portion of the other adjacent one of the plate-like radiating fins is the gap. As a result, even when the plurality of plate-like radiating fins are integrated, the cooling air flows through the gap. Therefore, the increase of the pressure loss of the cooling air can be prevented.

According to an aspect of the heat sink of the present disclosure, the fin base portions of the plurality of plate-like radiating fins are integrated, and the twisted portion of the plate-like radiating fin is connected to the twisted portion of the other adjacent plate-like radiating fin via the joining portion. As a result, the surface area of the plate-like radiating fins including the joining portion increases to be able to contribute to improvement of the heat dissipation amount. The twisted portion of the plate-like radiating fin is connected to the twisted portion of the other adjacent plate-like radiating fin via the joining portion. As a result, noise generation when the cooling air flowing through the plate-like radiating fins can be prevented in a more reliable manner.

According to an aspect of the heat sink of the present disclosure, the twist start portion is positioned between the one end and the other end, and the twisted portion has the first planar region defined by the one end portion that is at least a part of the one end facing the twist start portion and inclines at the angle θ1 in the main front surface direction of the base plate with respect to the twist start portion, and the first fin tip portion that is a part of the fin tip facing the fin base portion and inclines at the angle θ2 along the extending direction of the main front surface of the base plate to the one end portion from the twist start portion, with respect to the stretching direction of the fin base portion, and the second planar region defined by the other end portion that is at least a part of the other end facing the twist start portion and inclines at the angle θ3 in the main front surface direction of the base plate with respect to the twist start portion, and the second fin tip portion that is a part of the fin tip facing the fin base portion and inclines at the angle θ4 along the extending direction of the main front surface of the base plate to the other end portion from the twist start portion with respect to the stretching direction of the fin base portion. As a result, the generation position of the cooling air at a high flow rate in the fin base portion can be adjusted. Therefore, even when the position where the heat-generating element is thermally connected is not a center portion of the base plate, the heat-generating element can be more efficiently cooled.

According to an aspect of the heat sink of the present disclosure, the inclining direction of the angle θ1 with respect to the twist start portion is opposite to the inclining direction of the angle θ3 with respect to the twist start portion, and the inclining direction of the angle θ2 with respect to the stretching direction of the fin base portion is opposite to the inclining direction of the angle θ4 with respect to the stretching direction of the fin base portion. As a result, the flow of the cooling air in the fin tip direction is promoted in the first planar region and/or the second planar region. Therefore, the increase of the pressure loss of the cooling air can be further prevented.

According to an aspect of the heat sink of the present disclosure, the inclining direction of the angle θ1 with respect to the twist start portion is the same as the inclining direction of the angle θ3 with respect to the twist start portion, and the inclining direction of the angle θ2 with respect to the stretching direction of the fin base portion is the same as the inclining direction of the angle θ4 with respect to the stretching direction of the fin base portion. As a result, the flow of the cooling air is guided to the fin base portion of the plate-like radiating fin and the flow rate of the cooling air in the fin base portion is increased, in both regions of the first planar region and the second planar region. Therefore, the difference between the temperature of the fin base portion and the average temperature of the radiating fin can be further reduced.

According to an aspect of the heat sink of the present disclosure, the fin base portion has a planar surface portion extending from the one end to the other end in the width direction of the plate-like radiating fin. As a result, the flow of the cooling air at a high flow rate in the fin base portion is smoothened, and the difference between the temperature of the fin base portion and the average temperature of the plate-like radiating fin can be further reduced.

According to an aspect of the heat sink of the present disclosure, the top surface portion having the planar surface shape further extends from the fin tip. As a result, by causing the top surface portion to abut against the adjacent plate-like radiating fin, the mechanical strength of the radiating fin group formed by the plurality of plate-like radiating fins is improved.

According to an aspect of the heat sink of the present disclosure, the bottom surface portion having the planar surface shape further extends from the bottom portion of the fin base portion along the extending direction of the main front surface of the base plate. As a result, the thermal connectivity between the base plate and the plate-like radiating fin is improved. According to an aspect of the heat sink of the present disclosure, by causing the bottom surface portion to abut against the adjacent plate-like radiating fin, the mechanical strength of the radiating fin group formed by the plurality of plate-like radiating fins is improved.

According to an aspect of the heat sink of the present disclosure, the height of the fin base portion with respect to the height of the plate-like radiating fin is 30% or less. As a result, the cooling air also flows easily in the fin tip direction, while the flow of the cooling air is guided to the fin base portion of the plate-like radiating fin in a more reliable manner and the flow rate of the cooling air in the fin base portion is reliably increased. Therefore, the increase of the pressure loss of the cooling air can be reliably prevented.

### BRIEF DESCRIPTION OF THE DRAWINGS

FIG. 1 is a perspective view of a heat sink according to a first embodiment of the present disclosure;

FIG. 2 is a side view of the heat sink according to the first embodiment of the present disclosure;

FIG. 3 is a plan view of the heat sink according to the first embodiment of the present disclosure;

FIG. 4 is an explanatory view on a front side of an inclination angle in a twisted portion of a plate-like radiating fin included in the heat sink according to the first embodiment of the present disclosure;

FIG. 5 is an explanatory view on a rear side of the inclination angle in the twisted portion of the plate-like radiating fin included in the heat sink according to the first embodiment of the present disclosure;

FIG. 6 is a side view of the plate-like radiating fin included in the heat sink according to the first embodiment of the present disclosure;

FIG. 7 is an explanatory view of the twisted portion of the plate-like radiating fin included in the heat sink according to the first embodiment of the present disclosure;

FIG. 8 is an explanatory view of a flow of cooling air on the front side of the plate-like radiating fin included in the heat sink according to the first embodiment of the present disclosure;

FIG. 9 is an explanatory view of a flow of cooling air on the rear side of the plate-like radiating fin included in the heat sink according to the first embodiment of the present disclosure;

FIG. 10 is a perspective view of a heat sink according to a second embodiment of the present disclosure;

FIG. 11 is a perspective view of plate-like radiating fins included in the heat sink according to the second embodiment of the present disclosure;

FIG. 12 is an explanatory view of a flow of cooling air on a front side of plate-like radiating fins included in the heat sink according to the second embodiment of the present disclosure;

FIG. 13 is a perspective view of a plate-like radiating fin included in a heat sink according to a third embodiment of the present disclosure;

FIG. 14 is a plan view of the plate-like radiating fin included in the heat sink according to the third embodiment of the present disclosure;

FIG. 15 is a side view of the plate-like radiating fin included in the heat sink according to the third embodiment of the present disclosure;

FIG. 16 is an explanatory view of a flow of cooling air on a front side of the plate-like radiating fin included in the heat sink according to the third embodiment of the present disclosure;

FIG. 17 is a perspective view of a heat sink according to a fourth embodiment of the present disclosure;

FIG. 18 is a front view of the heat sink according to the fourth embodiment of the present disclosure;

FIG. 19 is a plan view of the heat sink according to the fourth embodiment of the present disclosure;

FIG. 20 is a perspective view of a heat sink according to a fifth embodiment of the present disclosure;

FIG. 21 is a perspective view of a plate-like radiating fin included in the heat sink according to the fifth embodiment of the present disclosure;

FIG. 22 is a perspective view of a heat sink according to a sixth embodiment of the present disclosure;

FIG. 23 is a side view of plate-like radiating fins included in the heat sink according to the sixth embodiment of the present disclosure;

FIG. 24 is a perspective view of the plate-like radiating fins included in the heat sink according to the sixth embodiment of the present disclosure; and

FIG. 25 is a perspective view a plate-like radiating fin included in a heat sink according to a seventh embodiment of the present disclosure.

### DETAILED DESCRIPTION

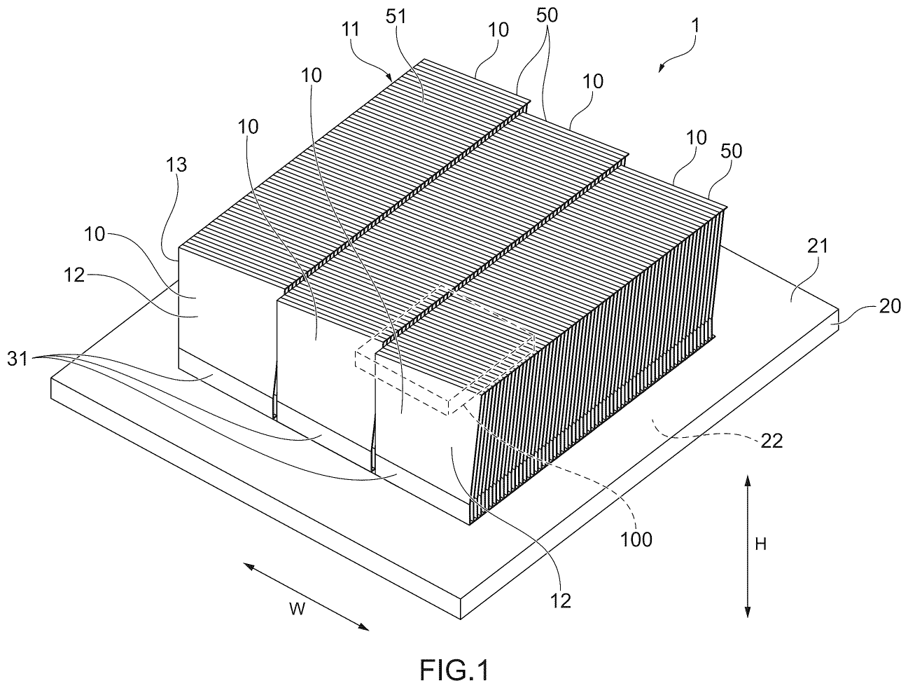

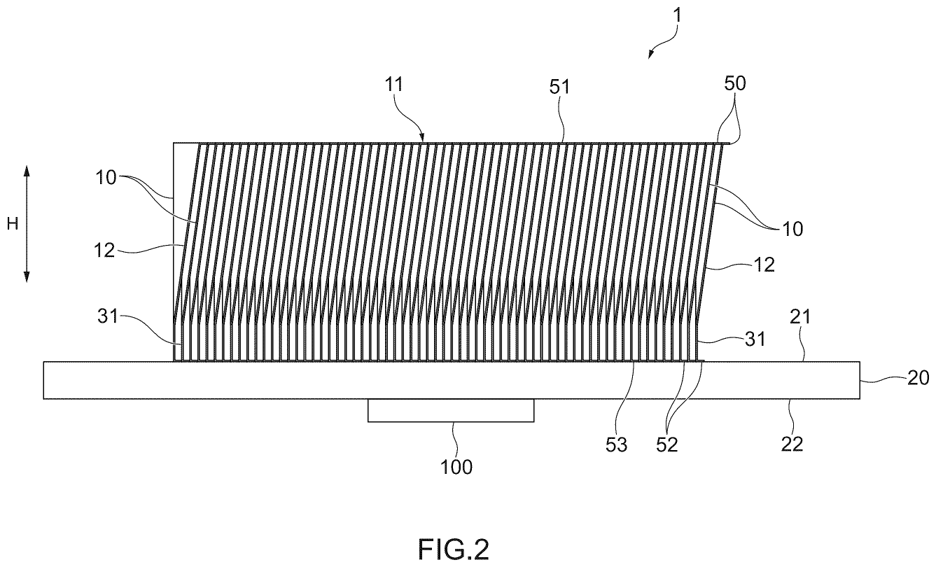

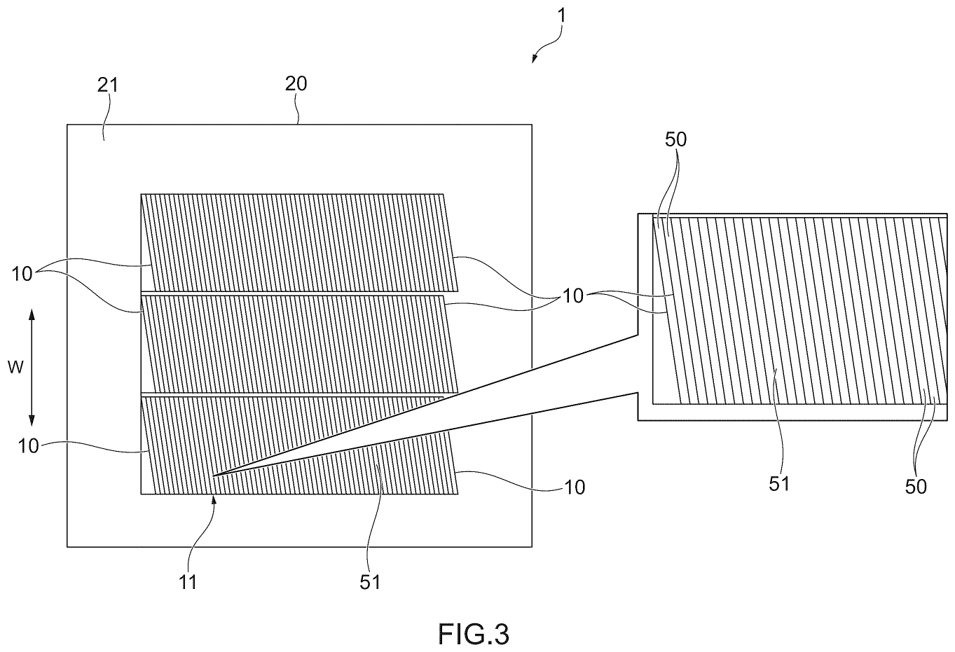

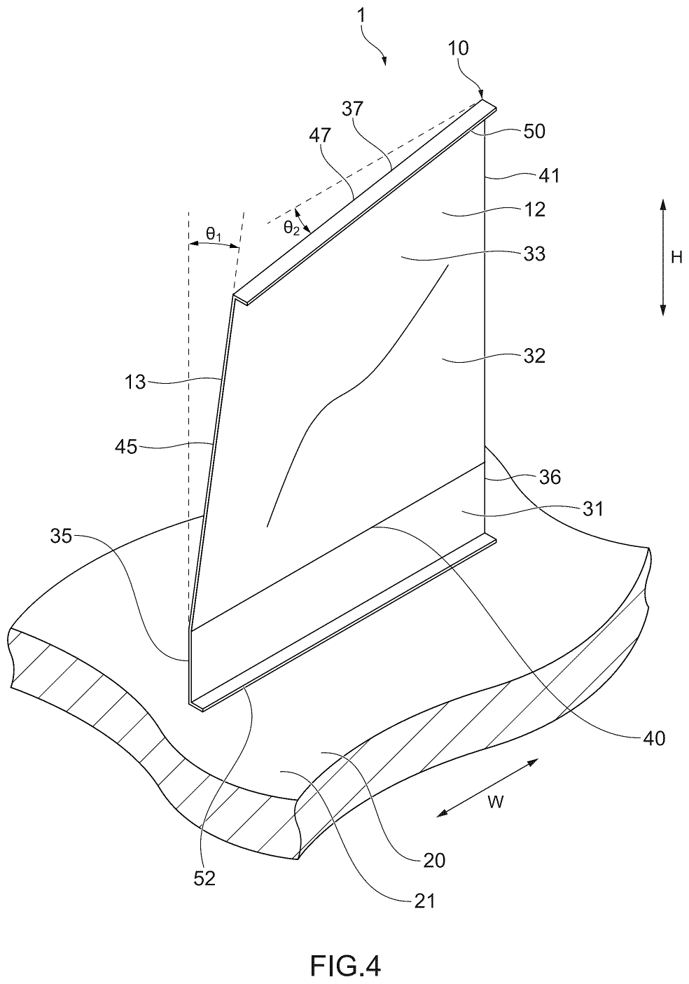

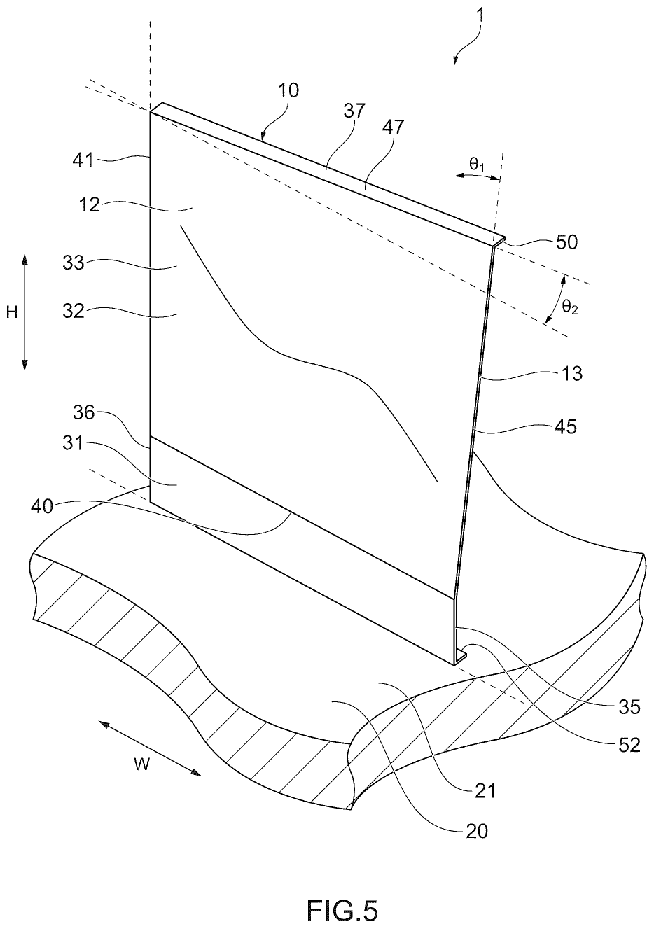

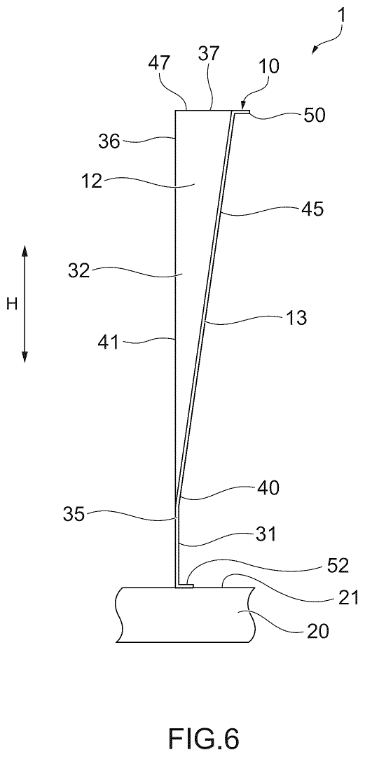

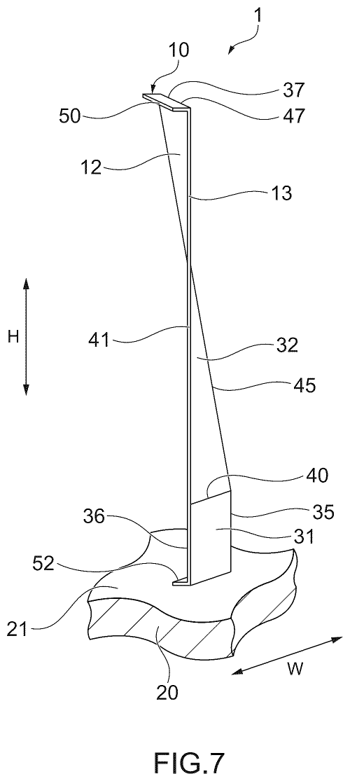

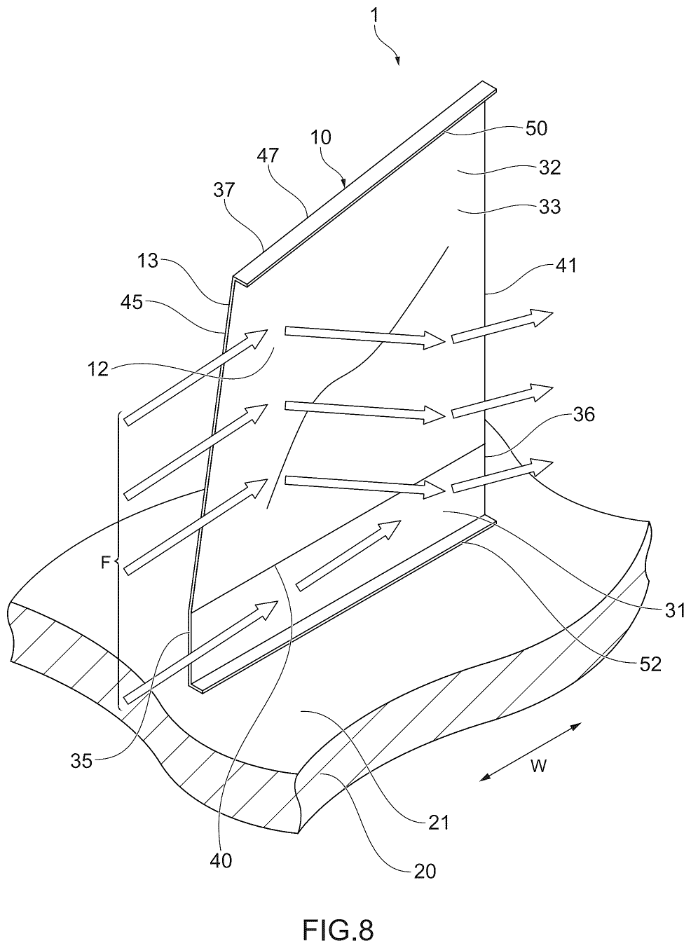

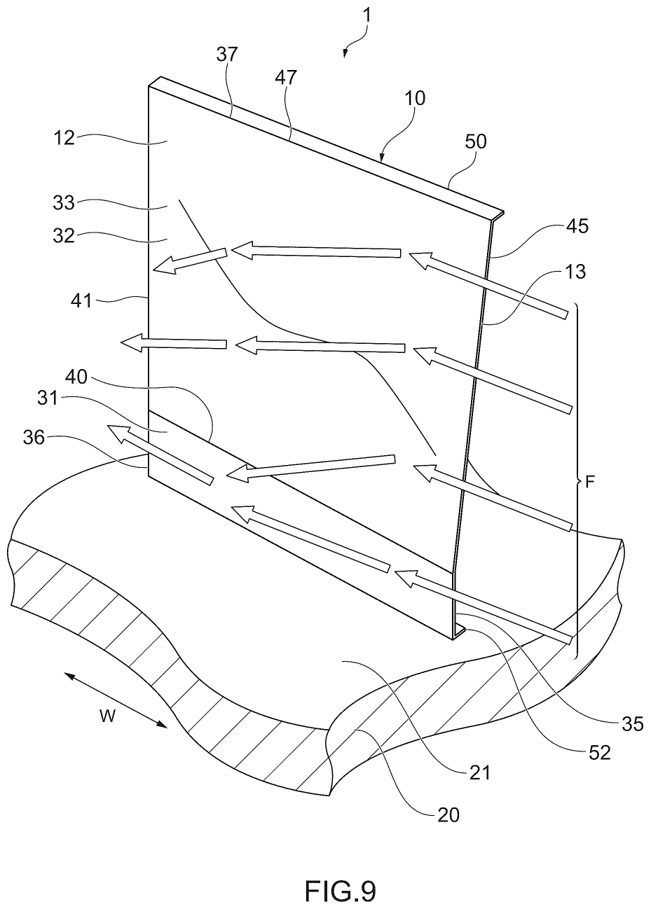

Hereinafter, heat sinks according to embodiments of the present disclosure will be described with reference to the accompanying drawings. First, a heat sink according to a first embodiment of the present disclosure will be described with reference to the accompanying drawings. Note that FIG. 1 is a perspective view of the heat sink according to the first embodiment of the present disclosure. FIG. 2 is a side view of the heat sink according to the first embodiment of the present disclosure. FIG. 3 is a plan view of the heat sink according to the first embodiment of the present disclosure. FIG. 4 is an explanatory view on a front side of an inclination angle in a twisted portion of a plate-like radiating fin included in the heat sink according to the first embodiment of the present disclosure. FIG. 5 is an explanatory view on a rear side of the inclination angle in the twisted portion of the plate-like radiating fin included in the heat sink according to the first embodiment of the present disclosure. FIG. 6 is a side view of the plate-like radiating fin included in the heat sink according to the first embodiment of the present disclosure. FIG. 7 is an explanatory view of the twisted portion of the plate-like radiating fin included in the heat sink according to the first embodiment of the present disclosure. FIG. 8 is an explanatory view of a flow of cooling air on the front side of the plate-like radiating fin included in the heat sink according to the first embodiment of the present disclosure. FIG. 9 is an explanatory view of a flow of cooling air on the rear side of the plate-like radiating fin included in the heat sink according to the first embodiment of the present disclosure.

As illustrated in FIGS. 1 to 3, a heat sink 1 according to the first embodiment includes a base plate 20 having a flat-plate-like shape, and a plurality of plate-like radiating fins 10, 10, 10 . . . that are erected on the base plate 20. The plate-like radiating fins 10 are directly attached onto a main front surface 21 of the base plate 20, and hence the plate-like radiating fins 10 are thermally connected to the base plate 20. The plate-like radiating fins 10 are thermally connected to the base plate 20 by being erected on the main front surface 21 of the base plate 20 at a predetermined angle with respect to an extending direction of the main front surface 21 of the base plate 20. The plurality of plate-like radiating fins 10, 10, 10 . . . form a radiating fin group 11 by being parallelly disposed on the main front surface 21 of the base plate 20.

The base plate 20 is thermally connected to a heat-generating element 100 that is a cooling target. The heat-generating element 100 abuts against a heat receiving surface 22 of the base plate 20 opposite from the main front surface 21. As a result, the base plate 20 is thermally connected to the heat-generating element 100. The base plate 20 is formed by a thermally conductive member. As the thermally conductive member, for example, metal members of copper, copper alloy, and the like can be listed.

The plate-like radiating fin 10 has main front surfaces 12 and side surfaces 13. The main front surface 12 of the plate-like radiating fin 10 has a width direction W and a height direction H. In the plate-like radiating fin 10, the main front surfaces 12 mainly contribute to the heat dissipation of the plate-like radiating fin 10. The width of the side surface 13 forms the thickness of the plate-like radiating fin 10. The material of the plate-like radiating fin 10 is not particularly limited, and for example, copper, copper alloy, aluminum, aluminum alloy, and the like can be listed.

As illustrated in FIGS. 1 to 3, the plurality of plate-like radiating fins 10, 10, 10 . . . are parallelly disposed in a direction substantially parallel to the extending direction of the main front surfaces 12, 12, 12 . . . of the plurality of plate-like radiating fins 10, 10, 10 . . . and such that the main front surfaces 12, 12, 12 . . . of the plurality of plate-like radiating fins 10, 10, 10 . . . are substantially on a same plane. More specifically, as described below, fin base portions 31, 31, 31 . . . of the plurality of plate-like radiating fins 10, 10, 10 . . . are parallelly disposed such that the fin base portions 31, 31, 31 . . . are mutually in a substantially parallel direction and substantially on the same plane. The plurality of plate-like radiating fins 10, 10, 10 . . . are parallelly disposed to substantially be on a straight line in a direction substantially orthogonal to the extending direction of the main front surfaces 12 of the plurality of plate-like radiating fins 10, 10, 10. . . . More specifically, as described below, the fin base portions 31, 31, 31 . . . of the plurality of plate-like radiating fins 10, 10, 10 . . . are parallelly disposed to substantially be on a straight line in a direction substantially orthogonal to the extending direction of the fin base portions 31, 31, 31. . . . From the above, the main front surface 12 of the plate-like radiating fin 10 is disposed to be arranged to be substantially parallel to the main front surface 12 of another adjacent plate-like radiating fin 10. Therefore, the plurality of plate-like radiating fins 10, 10, 10 . . . are not disposed in an offset manner but are disposed in an aligned manner and form the radiating fin group 11. The plurality of plate-like radiating fins 10, 10, 10 . . . forming the heat sink 1 are parallelly disposed at substantially even intervals from one end to another end of the base plate 20.

As illustrated in FIGS. 1 to 3, the main front surface 12 of the plate-like radiating fin 10 has a plurality of regions in which extending directions of planar surface portions differ. Accordingly, the main front surface 12 of the plate-like radiating fin 10 does not extend on a same planar surface.

As illustrated in FIGS. 4 to 7, the main front surface 12 of the plate-like radiating fin 10 has, as a plurality of regions in which extending directions of the planar surface portions differ, the fin base portion 31, and a twisted portion 32 inclined with respect to the fin base portion 31.

The fin base portion 31 extends from one end 35 to another end 36 in the width direction W of the plate-like radiating fin 10 along the main front surface 21 of the base plate 20. The fin base portion 31 is a section connected to the main front surface 21 of the base plate 20. In the heat sink 1, the fin base portion 31 is a planar surface portion extending from the one end 35 of the plate-like radiating fin 10 to the other end 36 of the plate-like radiating fin 10 in the width direction W of the plate-like radiating fin 10. The fin base portion 31 extends rectilinearly along the main front surface 21 of the base plate 20. The fin base portion 31 is a thermal connecting portion of the plate-like radiating fin 10 with respect to the base plate 20, and the plate-like radiating fin 10 is attached to the base plate 20 by the fin base portion 31. In the heat sink 1, the fin base portion 31 is a flat surface. In the heat sink 1, the fin base portion 31 of the plate-like radiating fin 10 extends with a substantially constant height from the one end 35 to the other end 36 in the width direction W of the plate-like radiating fin 10.

In the heat sink 1, the fin base portion 31 is erected in the perpendicular direction with respect to the extending direction of the main front surface 21 of the base plate 20.

The twisted portion 32 is a section provided continuously from the fin base portion 31 in a height direction H of the plate-like radiating fin 10. The twisted portion 32 is a section inclined in a main front surface 21 direction of the base plate 20 with respect to the fin base portion 31.

As illustrated in FIGS. 4 and 5, the twisted portion 32 is a planar region 33 that is defined by a border 40 with the fin base portion 31, a twist start portion 41 stretched linearly from the fin base portion 31 along the height direction H of the plate-like radiating fin 10, one end portion 45 that is a part of one end 35 of the plate-like radiating fin 10 facing the twist start portion 41, and inclined at an angle θ1 in the main front surface 21 direction of the base plate 20 with respect to the twist start portion 41, and a fin tip portion 47 that is at least a part of a fin tip 37 facing the fin base portion 31, and inclined at an angle θ2 along the extending direction of the main front surface 21 of the base plate 20 (that is, a parallel direction with respect to the main front surface 21 of the base plate 20) from the twist start portion 41 to the one end portion 45 with respect to the stretching direction of the fin base portion 31 (that is, the width direction W of the plate-like radiating fin 10). From the above, the twisted portion 32 is a planar surface portion surrounded by the border 40, the twist start portion 41, the one end portion 45 that is a part of the one end 35 of the plate-like radiating fin 10, and the fin tip portion 47, of the plate-like radiating fin 10. An outer edge of the twisted portion 32 is formed by the border 40, the twist start portion 41, the one end portion 45 that is a part of the one end 35 of the plate-like radiating fin 10, and the fin tip portion 47, of the plate-like radiating fin 10. Note that the twist start portion 41 is a rectilinear section stretched in the height direction H of the plate-like radiating fin 10 on a same plane as the fin base portion 31, and is a section to be a starting point of the twisted portion 32 in the height direction H of the plate-like radiating fin 10.

In the heat sink 1, the twist start portion 41 of the twisted portion 32 stretches rectilinearly in the perpendicular direction with respect to the extending direction of the main front surface 21 of the base plate 20. The twist start portion 41 stretches from the fin base portion 31 to the fin tip 37 in a same direction as the stretching direction of the fin base portion 31 with the border 40 as the starting point along the height direction H of the plate-like radiating fin 10. The twist start portion 41 stretches in a parallel direction with respect to a section of the fin base portion 31 of the one end 35 of the plate-like radiating fin 10.

In the heat sink 1, the twist start portion 41 is positioned at the other end 36 of the plate-like radiating fin 10, and is a part of the other end 36. Accordingly, the other end 36 of the plate-like radiating fin 10 is in an aspect in which a whole of the other end 36 stretches rectilinearly. The twisted portion 32 extends from the one end 35 to the other end 36 of the plate-like radiating fin 10 in the width direction W of the plate-like radiating fin 10.

The one end portion 45 of the twisted portion 32 inclines at the predetermined angle θ1 in the main front surface 21 direction of the base plate 20 with respect to the twist start portion 41, with the border 40 as the starting point. The one end portion 45 of the twisted portion 32 stretches rectilinearly to the fin tip 37. From the above, the one end portion 45 of the twisted portion 32 stretches in the direction of the angle θ1 with respect to the stretching direction of the twist start portion 41. The one end portion 45 of the twisted portion 32 inclines at the angle θ1 in the main front surface 21 direction of the base plate 20 with respect to the section of the fin base portion 31 of the one end 35 of the plate-like radiating fin 10. Accordingly, the one end 35 of the plate-like radiating fin 10 is in an aspect in which the one end 35 bends at the angle θ1 in the border 40.

The fin tip portion 47 of the twisted portion 32 inclines at the predetermined angle θ2 along the extending direction of the main front surface 21 of the base plate 20 from the twist start portion 41 to the one end portion 45 with respect to the stretching direction of the fin base portion 31 in the width direction W of the plate-like radiating fin 10, with the twist start portion 41 as a starting point. The fin tip portion 47 of the twisted portion 32 rectilinearly stretches to the one end portion 45 from the twist start portion 41. From the above, the fin tip portion 47 of the twisted portion 32 stretches in a direction of the angle θ2 with respect to the stretching direction of the fin base portion 31 in the width direction W of the plate-like radiating fin 10. In the heat sink 1, the entire fin tip 37 of the plate-like radiating fin 10 that faces the fin base portion 31 is the fin tip portion 47 of the twisted portion 32. Accordingly, the whole of the fin tip 37 of the plate-like radiating fin 10 rectilinearly stretches.

From the above, as illustrated in FIGS. 6 and 7, the one end 35 of the plate-like radiating fin 10 bends in the border 40 and stretches, whereas the entire other end 36 of the plate-like radiating fin 10 including the fin base portion 31 and the twisted portion 32 rectilinearly stretches. The fin tip portion 47 of the twisted portion 32 rectilinearly stretches in a different direction from the width direction of the fin base portion 31 from the twist start portion 41 to the one end portion 45. With respect to the extending direction of the main front surface 21 of the base plate 20, the one end portion 45 of the twisted portion 32 is further separate from the fin base portion 31 as the one end portion 45 of the twisted portion 32 progresses from the border 40 toward the fin tip portion 47, and the fin tip portion 47 of the twisted portion 32 is further separate from the fin base portion 31 as the one end portion 45 of the twisted portion 32 progresses from the twist start portion 41 toward the one end portion 45.

In the heat sink 1, the height of the plate-like radiating fin 10 is a substantially same height from the one end 35 to the other end 36. In the width direction W of the plate-like radiating fin 10, a width of the fin base portion 31 of the plate-like radiating fin 10 is substantially same as a width of the fin tip 37 of the plate-like radiating fin 10.

As illustrated in FIGS. 8 and 9, cooling air F that is supplied to the heat sink 1 from a blowing fan (not illustrated) is supplied to flow in a direction from the one end 35 to the other end 36 of the plate-like radiating fin 10. In other words, the cooling air F is supplied from the one end 35 toward the other end 36 in the width direction W of the plate-like radiating fin 10. As a result of the cooling air F being supplied to the heat sink 1, the heat sink 1 can exhibit excellent cooling performance. The cooling air F is supplied from a side facing the side surface 13 of the plate-like radiating fin 10 in the one end 35 to the heat sink 1, that is, to a space formed between the main front surfaces 12 of the adjacent plate-like radiating fins 10, to be along the main front surface 21 of the base plate 20. As a result of the cooling air F supplied to the heat sink 1 flowing along the main front surface 12 of the plate-like radiating fin 10 in the extending direction of the main front surface 21 of the base plate 20, the cooling air F cools the heat sink 1.

As illustrated in FIGS. 8 and 9, in the plate-like radiating fin 10 of the heat sink 1, the twisted portion 32 that is the planar region 33 in which extending direction differs from the fin base portion 31 guides the cooling air F in the direction from the fin tip 37 to the fin base portion 31. Mainly as a result of the one end portion 45 inclined at the angle θ1 in the main front surface 21 direction of the base plate 20 with respect to the twist start portion 41 being formed at the plate-like radiating fin 10, the one end portion 45 guides the cooling air F in the direction from the fin tip 37 to the fin base portion 31.

In the plate-like radiating fin 10, as described above, the front side of the twisted portion 32 guides the cooling air F in the direction from the fin tip 37 to the fin base portion 31. Therefore, also on the rear side of the twisted portion 32, a front side of a twisted portion in another adjacent plate-like radiating fin (not illustrated in FIGS. 8 and 9) facing the rear side of the twisted portion 32 guides the cooling air F in the direction from a fin tip to a fin base portion. Therefore, on the rear side of the twisted portion 32, the cooling air F is guided in the direction from the fin tip 37 to the fin base portion 31.

In the heat sink 1, the flow of the cooling air F is guided to the fin base portion 31 of the plate-like radiating fin 10 by the twisted portion 32, and a flow rate of the cooling air F in the fin base portion 31 is faster than a flow rate of the cooling air F in the fin tip 37. Therefore, in the plate-like radiating fin 10, the flow rate of the cooling air F in the fin base portion 31 that is closest to the base plate 20 and is likely to have a highest temperature becomes fast, and the flow rate of the cooling air F in the fin tip 37 that is farthest from the base plate 20 and is least likely to have a high temperature is moderately suppressed. Therefore, a difference between the temperature of the fin base portion 31 and an average temperature of the entire plate-like radiating fin 10 is reduced, and hence the plate-like radiating fin 10 has excellent fin efficiency.

In the heat sink 1, the planar region 33 of the twisted portion 32 extends from the twist start portion 41 to the one end portion 45 of the plate-like radiating fin 10, and from the border 40 with the fin base portion 31 to the fin tip portion 47. Therefore, the cooling air F supplied from the one end 35 toward the other end 36 of the plate-like radiating fin 10 also easily flows in the direction to the fin tip 37 and a vicinity of the fin tip 37 as it flows from the one end portion 45 to the twist start portion 41 while being guided to the fin base portion 31 of the plate-like radiating fin 10. Mainly as a result of the fin tip portion 47 of the twisted portion 32 stretching in the direction of the angle θ2 with respect to the stretching direction of the fin base portion 31 with the twist start portion 41 as the starting point, the cooling air F also easily flows in the direction to the fin tip 37 and the vicinity of the fin tip 37 as the cooling air F flows from the one end portion 45 to the twist start portion 41. As a result, in the heat sink 1, increase of pressure loss of the cooling air F that flows through the plate-like radiating fin 10 can be prevented. Therefore, the heat sink 1 can exhibit excellent heat dissipation characteristics.

As a result that of the plate-like radiating fin 10 having the fin base portion 31 and the twisted portion 32 in the heat sink 1, the cooling air F is easily separated from the main front surface 12 of the plate-like radiating fin 10 because the twisted portion 32 is a section protruding in a parallel direction to the main front surface 21 of the base plate 20 with respect to the fin base portion 31. Therefore, even when the plate-like radiating fins 10 are not disposed in an offset manner and are disposed in an aligned manner, the cooling air F is smoothly sent to between the adjacent plate-like radiating fins 10 parallelly disposed. From the above, the plate-like radiating fin 10 can generate turbulence in the cooling air F, and contribute to improvement in heat dissipation characteristics of the heat sink 1.

As a result that in the heat sink 1, the twist start portion 41 is positioned in at least a part of the other end 36, the twisted portion 32 extends to the other end 36 from the one end 35 in the width direction W of the plate-like radiating fin 10, guide of the cooling air F to the fin base portion 31 by the twisted portion 32 is further promoted, and fin efficiency of the plate-like radiating fin 10 is further improved. As a result that in the heat sink 1, the fin base portion 31 is the planar surface portion extending from the one end 35 to the other end 36 in the width direction W of the plate-like radiating fin 10, the flow of the cooling air F at a high flow rate in the fin base portion 31 is smoothened, and the difference between the temperature of the fin base portion 31 and the average temperature of the plate-like radiating fin 10 can be further reduced.

A ratio of the height of the fin base portion 31 to the height of the plate-like radiating fin 10 is not particularly limited, but is preferably 30% or less in terms of being able to reliably prevent increase of the pressure loss of the cooling air F as a result of the cooling air F also flowing easily in the direction to the fin tip 37 while the flow of the cooling air F is guided to the fin base portion 31 of the plate-like radiating fin 10 in a more reliably manner and the rate of the flow of the cooing air F in the fin base portion 31 is reliably increased. In the fin base portion 31 that is the planar surface portion extending from the one end 35 to the other end 36 in the width direction W of the plate-like radiating fin 10, a lower limit value of the ratio of the height of the fin base portion 31 to the height of the plate-like radiating fin 10 is not particularly limited as long as it exceeds 0%, but the lower limit value of the ratio is preferably 5% in terms of the cooling air F also flowing in the direction to the fin tip 37 more easily.

The angle θ1 that is the angle formed by the one end portion 45 and the twist start portion 41 with the border 40 as the starting point is not particularly limited as long as the angle θ1 exceeds 0 degrees, but a lower limit value of the angle θ1 is preferably 2.0 degrees, and more preferably 5.0 degrees, in terms of the twisted portion 32 being able to guide the cooling air F in the direction from the fin tip 37 to the fin base portion 31 in a more reliable manner. Meanwhile, an upper limit value of the angle θ1 is preferably 20 degrees, and more preferably 15 degrees, in terms of being able to prevent the decrease of the wind speed of the cooling air F among the plurality of plate-like radiating fins 10, 10, 10 . . . in a more reliable manner by preventing the increase of the pressure loss of the cooling air F in a more reliable manner.

The angle θ2 that is the angle formed by the fin tip portion 47 of the twisted portion 32 and the stretching direction of the fin base portion 31, with the twist start portion 41 as the starting point, is not particularly limited as long as the angle θ2 exceeds 0 degrees, but a lower limit value of the angle θ2 is preferably 2.0 degrees, and more preferably 5.0 degrees, in terms of the twisted portion 32 being able to guide the cooling air F in the direction from the fin tip 37 to the fin base portion 31 in a more reliable manner. Meanwhile, an upper limit value of the angle θ2 is preferably 20 degrees, and more preferably 15 degrees, in terms of being able to prevent the increase of the pressure loss of the cooling air F in a more reliable manner by also making it easy for the cooling air F to flow in the direction to the fin tip 37 and a vicinity of the fin tip 37.

As illustrated in FIGS. 1 to 9, in the plate-like radiating fin 10 of the heat sink 1, a top surface portion 50 having a planar surface shape further extends from the fin tip 37 stretching rectilinearly in the width direction W of the plate-like radiating fin 10. The top surface portion 50 is rectilinearly provided from the one end 35 to the other end 36 of the plate-like radiating fin 10. The top surface portion 50 extends in a substantially parallel direction to the extending direction of the main front surface 21 of the base plate 20.

As illustrated in FIGS. 1 to 3, as a result of the top surface portion 50 abutting against the fin tip 37 of the other adjacent plate-like radiating fin 10, a top surface 51 is formed on the radiating fin group 11 formed by the plurality of plate-like radiating fins 10, 10, 10. . . . As a result of the top surface portion 50 having a planar surface shape further extending from the fin tip 37, mechanical strength of the radiating fin group 11 formed by the plurality of plate-like radiating fins 10, 10, 10 . . . is improved by causing the top surface portion 50 to abut against the other adjacent plate-like radiating fin 10.

When the top surface portion 50 abuts against the fin tip 37 of the other adjacent plate-like radiating fin 10, a dimension in the extending direction of the top surface portion 50 of the plate-like radiating fin 10 defines a space width between the plate-like radiating fin 10 and the other adjacent plate-like radiating fin 10. A main function of the top surface portion 50 of the plate-like radiating fin 10 is to improve the mechanical strength of the radiating fin group 11, and hence the top surface portion 50 is not necessarily provided in terms of improving fin efficiency of the plate-like radiating fin 10.

As illustrated in FIG. 2 and FIGS. 4 to 9, in the plate-like radiating fin 10 of the heat sink 1, a bottom surface portion 52 having a planar surface shape further extends from a bottom portion of the fin base portion 31. The bottom surface portion 52 is provided to the other end 36 from the one end 35 of the plate-like radiating fin 10. The bottom surface portion 52 extends along the extending direction of the main front surface 21 of the base plate 20.

As illustrated in FIG. 2, as a result of the bottom surface portion 52 abutting against the fin base portion 31 of the other adjacent plate-like radiating fin 10, a bottom surface 53 is formed on the radiating fin group 11 formed by the plurality of plate-like radiating fins 10, 10, 10 . . . As a result of the bottom surface portion 52 having a planar surface shape further extending along the extending direction of the main front surface 21 of the base plate 20, from the bottom portion of the fin base portion 31, the thermal connectivity of the base plate 20 and the plate-like radiating fin 10 improves. In addition, the mechanical strength of the radiating fin group 11 formed by the plurality of plate-like radiating fins 10, 10, 10 . . . improves by causing the bottom surface portion 52 to abut against the fin base portion 31 of another adjacent plate-like radiating fin 10.

A dimension in the extending direction of the bottom surface portion 52 is substantially same as the dimension in the extending direction of the top surface portion 50, and when the bottom surface portion 52 abuts against the fin base portion 31 of another adjacent plate-like radiating fin 10, the dimension in the extending direction of the bottom surface portion 52 of the plate-like radiating fin 10 also defines a space width between the plate-like radiating fin 10 and the other adjacent plate-like radiating fin 10. A main function of the bottom surface portion 52 of the plate-like radiating fin 10 is to improve thermal connectivity with the base plate 20 and the mechanical strength of the radiating fin group 11, and hence the bottom surface portion 52 may not necessarily provided in terms of improving fin efficiency of the plate-like radiating fin 10.

In the heat sink 1, the plurality of plate-like radiating fins 10, 10, 10 . . . are parallelly disposed such that the fin base portions 31 are in a direction substantially parallel to the width direction W of the plate-like radiating fin 10 and substantially on the same plane. The plurality of plate-like radiating fins 10, 10, 10 . . . are parallelly disposed such that the fin base portions 31 are in a direction substantially orthogonal to the width direction W of the plate-like radiating fin 10 and substantially on a straight line. In the heat sink 1, the one end 35 of the plate-like radiating fin 10 does not contact the other end 36 of another adjacent plate-like radiating fin 10. In the plurality of plate-like radiating fins 10, 10, 10 . . . in which the fin base portions 31 are parallelly disposed in a direction substantially parallel to the width direction W of the plate-like radiating fin 10, a gap is formed between the plate-like radiating fin 10 and another adjacent plate-like radiating fin 10.

The plate-like radiating fin 10 is erected on the main front surface 21 of the base plate 20 at the predetermined angle with respect to the extending direction of the main front surface 21 of the base plate 20. The erection angle of the fin base portion 31 having a planar surface portion with respect to the extending direction of the main front surface 21 of the base plate 20 is not particularly limited, but a lower limit value of the erection angle is preferably 70 degrees and particularly preferably 80 degrees in terms of reliably securing the number of installations of the plate-like radiating fins 10 in a space in which the plate-like radiating fins 10 are installable. Meanwhile, it is preferred that an upper limit value of the erection angle of the fin base portion 31 having a planar surface portion with respect to the extending direction of the main front surface 21 of the base plate 20 be 90 degrees, in other words, the plate-like radiating fin 10 be erected such that the fin base portion 31 becomes perpendicular to the main front surface 21 of the base plate 20. The erection angle of the fin base portion 31 having a planar surface portion means an erection angle of the fin base portion 31 with respect to the extending direction of the base plate 20 in the main front surface 12 on a side on which the twisted portion 32 protrudes with respect to the fin base portion 31 out of both of the main front surfaces 12 of the plate-like radiating fin 10.

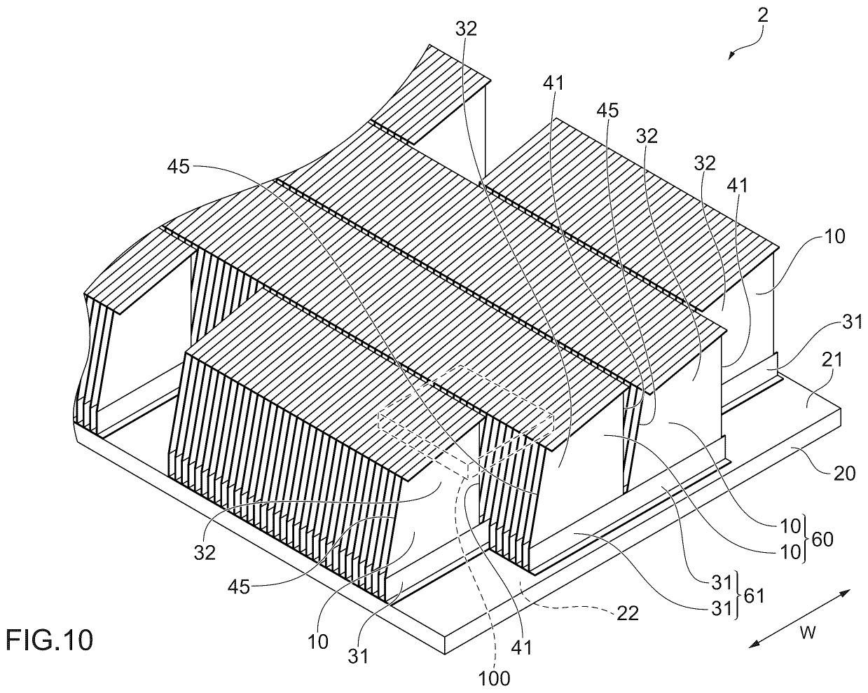

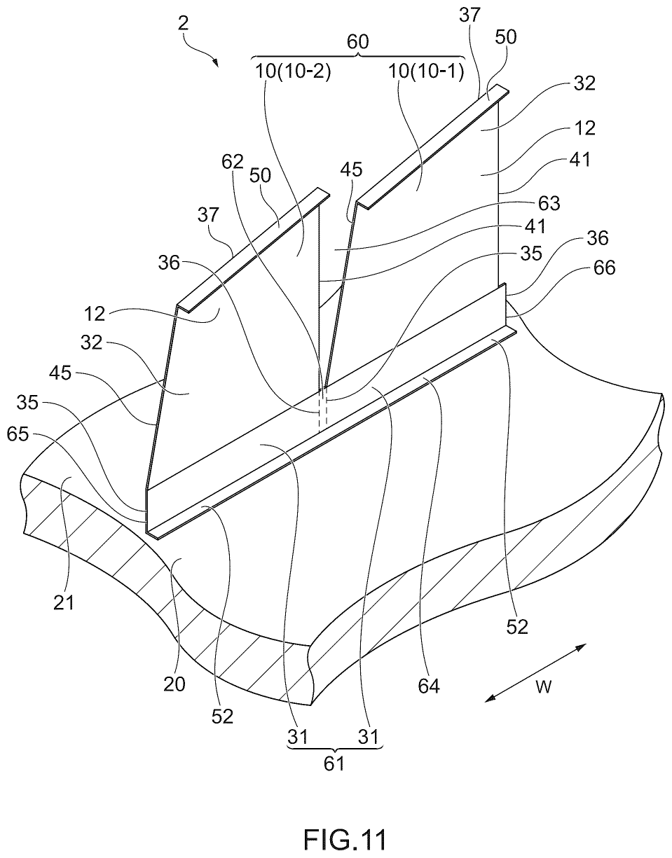

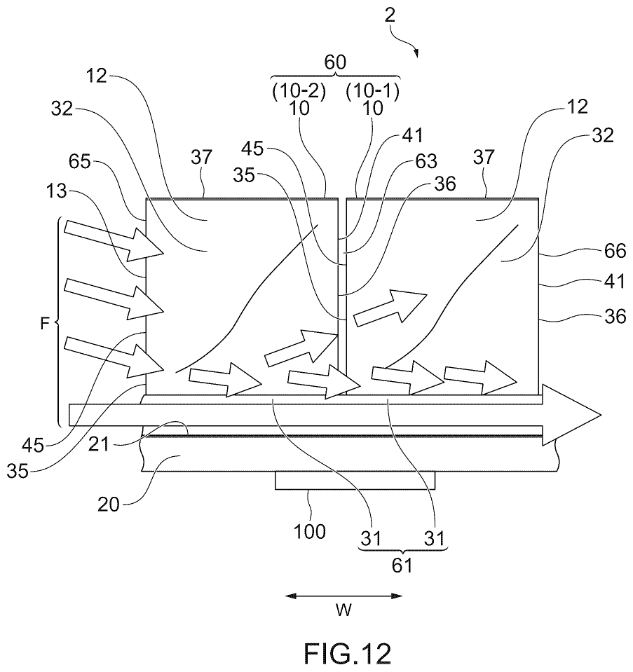

Next, a heat sink according to a second embodiment of the present disclosure will be described with reference to the accompanying drawings. The heat sink according to the second embodiment is in common with the heat sink according to the first embodiment in terms of main components, and hence the same components as those of the heat sink according to the first embodiment are described with use of the same reference characters. FIG. 10 is a perspective view of the heat sink according to the second embodiment of the present disclosure. FIG. 11 is a perspective view of the plate-like radiating fin included in the heat sink according to the second embodiment of the present disclosure. FIG. 12 is an explanatory view of a flow of cooling air on a front side of the plate-like radiating fin included in the heat sink according to the second embodiment of the present disclosure.

In the heat sink 1 according to the first embodiment, regarding the plate-like radiating fins 10 parallelly disposed in a direction substantially parallel to the width direction W of the plate-like radiating fin 10, the gap is formed between the plate-like radiating fin 10 and another adjacent plate-like radiating fin, and the plate-like radiating fin 10 and the other adjacent plate-like radiating fin 10 are separate bodies. However, instead of this, as illustrated in FIG. 10, in a heat sink 2 according to the second embodiment, a plate-like radiating fin 10 and another adjacent plate-like radiating fin 10 are integrated.

In the heat sink 2, a plurality of plate-like radiating fins 10, 10, 10 . . . are disposed along a width direction of a fin base portion 31 (that is, a width direction W of the plate-like radiating fin 10), and an end portion in the width direction of the fin base portion 31 of the plate-like radiating fin 10 is connected to an end portion in a width direction of a fin base portion 31 of another adjacent plate-like radiating fin 10. Thereby, the plurality of plate-like radiating fins 10, 10, 10 . . . are integrated, and an integrated plate-like radiating fin 60 is formed. From the above, the integrated plate-like radiating fin 60 has an integrated fin base portion 61 that is an aspect in which a plurality of fin base portions 31 of the plate-like radiating fins 10 are integrated. The number of plate-like radiating fins 10 that form the integrated plate-like radiating fin 60 is not particularly limited. However, in the heat sink 2, two plate-like radiating fins 10 are integrated, and the integrated plate-like radiating fin 60 is formed, for convenience of explanation.

As illustrated in FIG. 10, in the heat sink 2, in a center portion of the base plate 20 in the width direction W of the plate-like radiating fin 10, a plurality of integrated plate-like radiating fins 60, 60, 60 . . . are parallelly disposed to be in a direction substantially orthogonal to the width direction W of the plate-like radiating fin 10 and substantially on a straight line. On both edge portions of the base plate 20, a plurality of plate-like radiating fins 10, 10, 10 . . . that are not integrated are parallelly disposed to be substantially on a straight line in the direction substantially orthogonal to the width direction W of the plate-like radiating fin 10 and substantially on a straight line. In FIG. 10, the integrated plate-like radiating fins 60 and the plate-like radiating fins 10 that are not integrated are used, but all the plate-like radiating fins may be the integrated plate-like radiating fins 60 without using the plate-like radiating fins 10 that are not integrated.

As illustrated in FIG. 11, in the integrated plate-like radiating fin 60, in a fin base portion 31, one end 35 in a width direction W of a plate-like radiating fin 10-1 is connected to another end 36 in the width direction W of another adjacent plate-like radiating fin 10-2 in the fin base portion 31, and thereby the plurality of plate-like radiating fins 10 are integrated. In the fin base portion 31, the one end 35 in the width direction W of the plate-like radiating fin 10-1 is connected to the other end 36 in the width direction W of the other adjacent plate-like radiating fin 10-2 via a connecting portion 62. The one end 35 in the width direction W of the other plate-like radiating fin 10-2 is one end 65 of the integrated plate-like radiating fin 60, and the other end 36 in the width direction W of the plate-like radiating fin 10-1 is another end 66 of the integrated plate-like radiating fin 60.

In the heat sink 2, a space between a twisted portion 32 of the plate-like radiating fin 10-1 and a twisted portion 32 of the other adjacent plate-like radiating fin 10-2 is a gap 63. Therefore, the twisted portion 32 of the plate-like radiating fin 10-1 and the twisted portion 32 of the other adjacent plate-like radiating fin 10-2 are separate bodies. In the heat sink 2, a top surface portion 50 having a planar surface shape also further extends from a fin tip 37 stretching rectilinearly in the width direction W of the plate-like radiating fin 10. The top surface portion 50 rectilinearly stretches in the width direction W of the radiating fin 10. In the heat sink 2, a top surface portion 50 of the plate-like radiating fin 10-1 is provided from the one end 35 to the other end 36 of the plate-like radiating fin 10-1. A top surface portion 50 of the other plate-like radiating fin 10-2 is provided from one end 35 to the other end 36 of the other plate-like radiating fin 10-2. The top surface portion 50 of the plate-like radiating fin 10-1 and the top surface portion 50 of the other plate-like radiating fin 10-2 are not connected, and hence the top surface portion 50 of the plate-like radiating fin 10-1 and the top surface portion 50 of the other plate-like radiating fin 10-2 are separate bodies. Meanwhile, a bottom surface portion 52 of the plate-like radiating fin 10-1 and a bottom surface portion 52 of the other plate-like radiating fin 10-2 are connected. The bottom surface portion 52 of the plate-like radiating fin 10-1 and the bottom surface portion 52 of the other plate-like radiating fin 10-2 are integrated, and an integrated bottom surface portion 64 is formed.

As illustrated in FIG. 12, cooling air F supplied from a blower fan (not illustrated) to the heat sink 2 is supplied to flow in a direction from one end 65 of the integrated plate-like radiating fin 60, that is, the one end 35 of the other plate-like radiating fin 10-2 to another end 66 of the integrated plate-like radiating fin 60, that is, the other end 36 of the plate-like radiating fin 10-1. From the above, the cooling air F is supplied from the one end 65 to the other end 66 in the width direction W of the integrated plate-like radiating fin 60. As a result of the cooling air F being supplied to the heat sink 2, the heat sink 2 can exhibit excellent cooling performance. The cooling air F is supplied to the heat sink 2 from a side facing a side surface 13 of the plate-like radiating fin 10-2 in the one end 65 of the integrated plate-like radiating fin 60. The cooling air F supplied to the heat sink 2 flows along a main front surface 12 of the other plate-like radiating fin 10-2 and a main front surface 12 of the plate-like radiating fin 10-1 in an extending direction of a main front surface 21 of a base plate 20, and thereby cools the heat sink 2.

As illustrated in FIG. 12, in the integrated plate-like radiating fin 60 of the heat sink 2, the twisted portion 32 of the other plate-like radiating fin 10-2 of which extending direction differs from that of an integrated fin base portion 61 guides the cooling air F in a direction to the fin base portion 31 (integrated fin base portion 61) from the fin tip 37 of the other plate-like radiating fin 10-2. Mainly as a result of one end portion 45 inclined at an angle θ1 in a main front surface 21 direction of the base plate 20 with respect to a twist start portion 41 being formed at the other plate-like radiating fin 10-2, the cooling air F is guided in a direction from the fin tip 37 of the other plate-like radiating fin 10-2 to the fin base portion 31 (integrated fin base portion 61).

In the integrated plate-like radiating fin 60, even when a flow of the cooling air F in the direction to the fin tip 37 from the fin base portion 31 is formed, due to the gap 63 between the twisted portion 32 of the other plate-like radiating fin 10-2 and the twisted portion 32 of the plate-like radiating fin 10-1, the twisted portion 32 in which extending direction differs from that of the integrated fin base portion 61, of the plate-like radiating fin 10-1 positioned on the leeward of the other plate-like radiating fin 10-2 guides the cooling air F in the direction from the fin tip 37 of the plate-like radiating fin 10-1 to the fin base portion 31 (integrated fin base portion 61). Mainly as a result of the one end portion 45 inclined at the angle θ1 in the main front surface 21 direction of the base plate 20 with respect to the twist start portion 41 being formed at the plate-like radiating fin 10-1, the one end portion 45 guides the cooling air F in the direction from the fin tip 37 of the plate-like radiating fin 10-1 to the fin base portion 31 (integrated fin base portion 61).

In the integrated plate-like radiating fin 60, the front side of the twisted portion 32 guides the cooling air F in the direction from the fin tip 37 to the fin base portion 31 (integrated fin base portion 61) as described above. Therefore, on the rear side of the twisted portion 32, a front side of a twisted portion in another adjacent integrated plate-like radiating fin (not illustrated in FIG. 12) facing the rear side of the twisted portion 32 also guides the cooling air F in the direction from the fin tip to the fin base portion. Therefore, on the rear side of the twisted portion 32, the cooling air F is guided in the direction from the fin tip 37 to the fin base portion 31 (integrated fin base portion 61).

In the heat sink 2, as a result of the integrated plate-like radiating fin 60 being formed by the fin base portions 31 of the plurality of plate-like radiating fins 10 being integrated, the flow of the cooling air F becomes a continuous flow at a high flow rate in the integrated fin base portion 61. Therefore, a difference between a temperature of the fin base portion 31 and an average temperature of the plate-like radiating fin 10 can be further reduced, and more excellent fin efficiency can be obtained.

In the heat sink 2, as a result of the space between the twisted portion 32 of the plate-like radiating fin 10-1 and the twisted portion 32 of the other adjacent plate-like radiating fin 10-2 being the gap 63, the cooling air F flows through the gap 63, and hence increase of the pressure loss of the cooling air F can be reliably prevented, even if the plurality of plate-like radiating fins 10 are integrated.

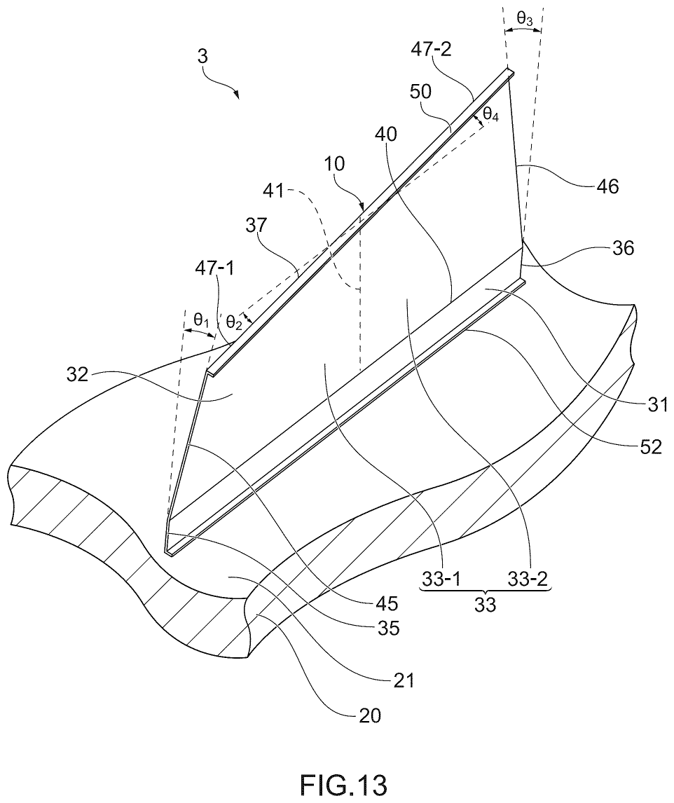

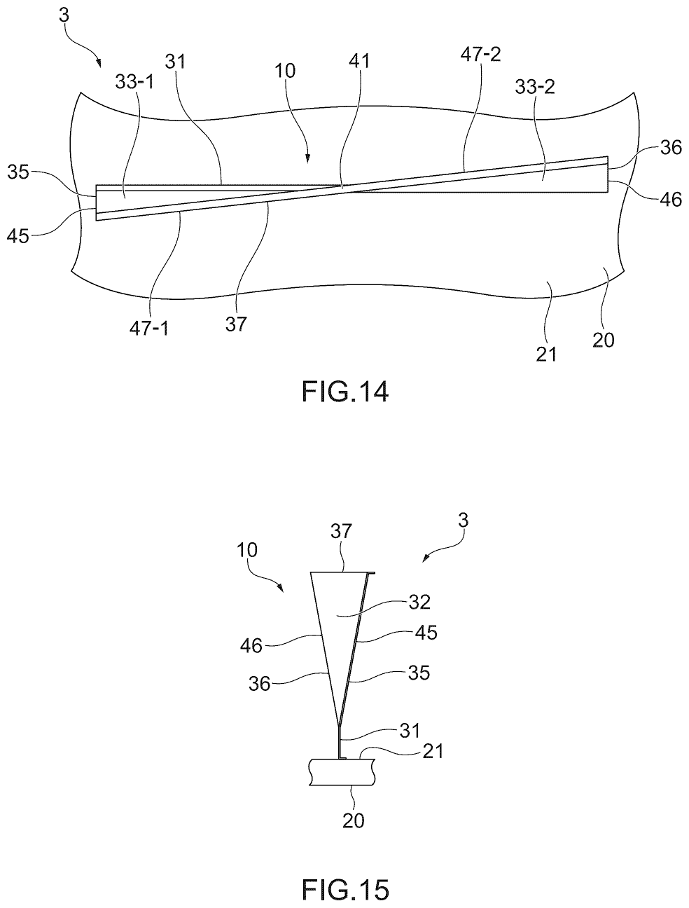

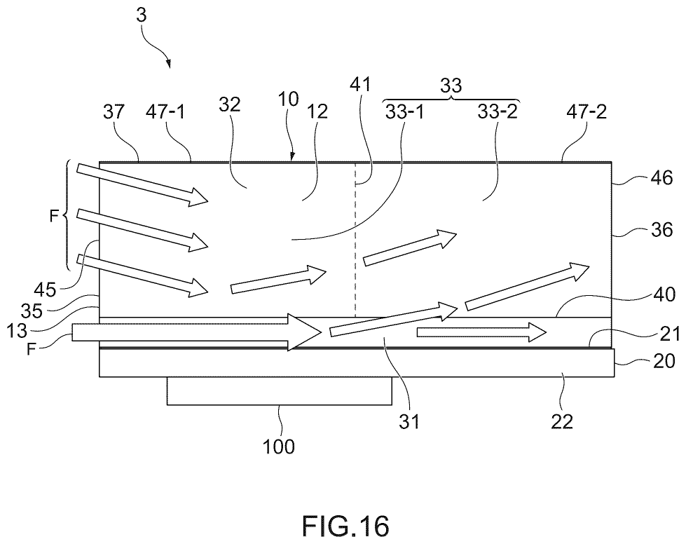

Next, a heat sink according to a third embodiment of the present disclosure will be described with reference to the accompanying drawings. The heat sink according to the third embodiment is in common with the heat sinks according to the first and second embodiments in terms of main components, and hence the same components as those of the heat sinks according to the first and second embodiments are described with use of the same reference characters. FIG. 13 is a perspective view of a plate-like radiating fin included in the heat sink according to the third embodiment of the present disclosure. FIG. 14 is a plan view of the plate-like radiating fin included in the heat sink according to the third embodiment of the present disclosure. FIG. 15 is a side view of the plate-like radiating fin included in the heat sink according to the third embodiment of the present disclosure. FIG. 16 is an explanatory view of a flow of cooling air on a front side of the plate-like radiating fin included in the heat sink according to the third embodiment of the present disclosure.

In the heat sink 1 according to the first embodiment, the twist start portion 41 is positioned at the other end 36 of the plate-like radiating fin 10, and is a part of the other end 36. However, Instead of this, as illustrated in FIGS. 13 and 14, in a heat sink 3 according to the third embodiment, a twist start portion 41 is positioned between one end 35 and another end 36 of a plate-like radiating fin 10.

In the heat sink 3, a twisted portion 32 of the plate-like radiating fin 10 has, as a planar region 33, a first planar region 33-1, and a second planar region 33-2 that has a different direction of inclination and/or degree of inclination with respect to a fin base portion 31 from the first planar region 33-1. In the heat sink 3, the first planar region 33-1 is from the one end 35 of the plate-like radiating fin 10 to the twist start portion 41, of the twisted portion 32, and the second planar region 33-2 is from the twist start portion 41 to the other end 36 of the plate-like radiating fin 10.

As illustrated in FIGS. 13 and 14, the first planar region 33-1 is defined by a border 40 with the fin base portion 31, the twist start portion 41, one end portion 45 that is a part of the one end 35 of the plate-like radiating fin 10 facing the twist start portion 41, and inclines at an angle θ1 in a direction to a main front surface 21 of a base plate 20 with respect to the twist start portion 41, and a first fin tip portion 47-1 that is a part of a fin tip 37 facing the fin base portion 31, and inclines at an angle θ2 along an extending direction of the main front surface 21 of the base plate 20 toward the one end portion 45 from the twist start portion 41, with respect to a stretching direction of the fin base portion 31.

The second planar region 33-2 is defined by the border 40 with the fin base portion 31, the twist start portion 41, another end portion 46 that is a part of the other end 36 of the plate-like radiating fin 10 facing the twist start portion 41, and inclines at an angle θ3 in the direction to the main front surface 21 of the base plate 20 with respect to the twist start portion 41, and a second fin tip portion 47-2 that is a part of the fin tip 37 facing the fin base portion 31, and inclines at an angle θ4 along the extending direction of the main front surface 21 of the base plate 20 from the twist start portion 41 toward the other end portion 46, with respect to the stretching direction of the fin base portion 31.

As illustrated in FIGS. 13 to 15, in the heat sink 3, an inclining direction of the angle θ1 of the one end portion 45 with respect to the twist start portion 41 in the first planar region 33-1 is opposite to an inclining direction of the angle θ3 of the other end portion 46 with respect to the twist start portion 41 in the second planar region 33-2. An inclining direction of the angle θ2 of the first fin tip portion 47-1 with respect to the stretching direction of the fin base portion 31 in the first planar region 33-1 is opposite to an inclining direction of the angle θ4 of the second fin tip portion 47-2 with respect to the stretching direction of the fin base portion 31 in the second planar region 33-2.

As illustrated in FIG. 16, cooling air F supplied to the heat sink 3 from a blower fan (not illustrated) is supplied to flow in a direction to the other end 36 from the one end 35 of the plate-like radiating fin 10. In other words, the cooling air F is supplied from the one end 35 toward the other end 36 in a width direction of the plate-like radiating fin 10. As a result of the cooling fan F being supplied to the heat sink 3, the heat sink 3 can exhibit excellent cooling performance. The cooling air F is supplied to the heat sink 3 from a side facing a side surface 13 of the plate-like radiating fin 10 in the one end 35, that is, to a space formed between main front surfaces 12 of adjacent plate-like radiating fins 10, to be along the main front surface 21 of the base plate 20. The cooling air F supplied to the heat sink 3 cools the heat sink 2 by flowing along the main front surface 12 of the plate-like radiating fin 10 in the extending direction of the main front surface 21 of the base plate 20.

As illustrated in FIG. 16, in the plate-like radiating fin 10 of the heat sink 3, the first planar region 33-1 of the twisted portion 32 of which extending direction differs from that of the fin base portion 31 guides the cooling air F in the direction to the fin base portion 31 from the fin tip 37. Mainly as a result of the one end portion 45 inclining at the angle θ1 in the main front surface 21 direction of the base plate 20 with respect to the twist start portion 41 being formed at the plate-like radiating fin 10, the one end portion 45 guides the cooling air F in the direction to the fin base portion 31 from the fin tip 37.

Meanwhile, the second planar region 33-2 of the twisted portion 32 in which extending direction differs from that of the fin base portion 31 guides the cooling air F in the direction from the fin base portion 31 to the fin tip 37. Mainly as a result of the other end portion 46 inclining at the angle θ3 in an opposite direction to the inclining direction of the angle θ1 in the main front surface 21 direction of the base plate 20 with respect to the twist start portion 41 being formed at the plate-like radiating fin 10, the other end portion 46 guides the cooling air F in the direction from the fin base portion 31 to the fin tip 37.

In the plate-like radiating fin 10, the front side of the first planar region 33-1 of the twisted portion 32 guides the cooling air F in the direction from the fin tip 37 to the fin base portion 31 as described above. Therefore, on the rear side of the first planar region 33-1 of the twisted portion 32, a front surface side of a first planar region in another adjacent plate-like radiating fin (not illustrated) facing the rear side of the first planar region 33-1 of the twisted portion 32 also guides the cooling air F in the direction from a fin tip to a fin base portion. Accordingly, on the rear side of the first planar region 33-1, the cooling air F is guided in the direction from the fin tip 37 to the fin base portion 31. As described above, as a result of the front side of the second planar region 33-2 of the twisted portion 32 guiding the cooling air F in the direction from the fin base portion 31 to the fin tip 37, a front side of a second planar region in another adjacent plate-like radiating fin facing a rear side of the second planar region 33-2 of the twisted portion 32 also guides the cooling air F in the direction from a fin base portion to a fin tip, on the rear side of the second planar region 33-2 of the twisted portion 32. Therefore, on the rear side of the second planar region 33-2, the cooling air F is guided in the direction from the fin base portion 31 to the fin tip 37.

In the heat sink 3, a generation position of the cooling air F at a high flow rate in the fin base portion 31 can be adjusted. Specifically, in the heat sink 3, the generation position of the cooling air F at a high flow rate can be moved in the direction to the one end 35 of the plate-like radiating fin 10. Therefore, in the heat sink 3, the heat-generating element 100 can be cooled more efficiently even when a position where the heat-generating element 100 is thermally connected is not the center portion of the base plate 20.

In the heat sink 3, as a result of the inclining direction of the angle θ1 of the one end portion 45 with respect to the twist start portion 41 being opposite to the inclining direction of the angle θ3 of the other end portion 46 with respect to the twist start portion 41, the flow of the cooling air F in the fin tip 37 direction is promoted in the second planar region 33-2. Therefore, increase of pressure loss of the cooling air F can be further prevented.

The angle θ1 that is the angle formed by the one end portion 45 and the twist start portion 41 with the border 40 as a starting point is not particularly limited as long as the angle θ1 exceeds 0 degrees, but a lower limit value of the angle θ1 is preferably 2.0 degrees, and more preferably 5.0 degrees in terms of the first planar region 33-1 of the twisted portion 32 being able to guide the cooling air F in the direction from the fin tip 37 to the fin base portion 31 in a more reliable manner. Meanwhile, an upper limit value of the angle θ1 is preferably 20 degrees, and more preferably 15 degrees in terms of being able to prevent increase of the pressure loss of the cooling air F in a more reliable manner, and prevent reduction of wind speed of the cooling air F among a plurality of plate-like radiating fins 10, 10, 10 . . . in a more reliable manner.

The angle θ3 that is the angle formed by the other end portion 46 inclining in the direction opposite to the inclining direction of the one end portion 45 and the twist start portion 41 with the border 40 as the starting point is not particularly limited as long as the angle θ3 exceeds 0 degrees, but a lower limit value is preferably 2.0 degrees, and more preferably 5.0 degrees in terms of being able to further prevent increase of pressure loss of the cooling air F. Meanwhile, an upper limit value of the angle θ3 is preferably 20 degrees and more preferably 15 degrees in terms of the cooling air F being guided in the direction from the fin base portion 31 to the fin tip 37 in a more reliable manner in the second planar region 33-2. The angle θ1 that is the angle formed by the one end portion 45 and the twist start portion 41 may be the same as or different from the angle θ3 that is the angle formed by the other end portion 46 and the twist start portion 41. When the angle θ1 and the angle θ3 are a same angle, the twist start portion 41 is positioned in the center portion between the one end 35 and the other end 36 of the plate-like radiating fin 10. When the angle θ1 is larger than the angle θ3, the twist start portion 41 is positioned in the other end 36 direction rather than the center portion between the one end 35 and the other end 36 of the plate-like radiating fin 10, and when the angle θ1 is smaller than the angle θ3, the twist start portion 41 is positioned in the one end 35 direction rather than the center portion between the one end 35 and the other end 36 of the plate-like radiating fin 10.

The angle θ2 that is the angle formed by the first fin tip portion 47-1 of the first planar region 33-1 and the stretching direction of the fin base portion 31 with the twist start portion 41 as the starting point is not particularly limited as long as the angle θ2 exceeds 0 degrees, and a lower limit value of the angle θ2 is preferably 2.0 degrees and more preferably 5.0 degrees in terms of the first planar region 33-1 being able to guide the cooling air F in the direction from the fin tip 37 to the fin base portion 31 in a more reliable manner. Meanwhile, an upper limit value of the angle θ2 is preferably 20 degrees and more preferably 15 degrees in terms of being able to make the cooling air F also flow easily in a direction to the fin tip 37 and a vicinity of the fin tip 37 and prevent increase of the pressure loss of the cooling air F in a more reliable manner.

The angle θ4 that is the angle formed by the second fin tip portion 47-2 of the second planar region 33-2 and the stretching direction of the fin base portion 31 with the twist start portion 41 as the starting point is not particularly limited as long as the angle θ4 exceeds 0 degrees, but a lower limit value is preferably 2.0 degrees and more preferably 5.0 degrees in terms of being able to further prevent the increase of the pressure loss of the cooling air F. Meanwhile, an upper limit value of the angle θ4 is preferably 20 degrees, and more preferably 15 degrees in terms of the cooling air F being guided in the direction from the fin base portion 31 to the fin tip 37 in a more reliable manner in the second planar region 33-2. The angle θ2 that is the angle formed by the first fin tip portion 47-1 of the first planar region 33-1 and the stretching direction of the fin base portion 31 may be the same as or different from the angle θ4 that is the angle formed by the second fin tip portion 47-2 of the second planar region 33-2 and the stretching direction of the fin base portion 31. When the angle θ2 and the angle θ4 are a same angle, the twist start portion 41 is positioned in the center portion between the one end 35 and the other end 36 of the plate-like radiating fin 10. When the angle θ2 is larger than the angle θ4, the twist start portion 41 is positioned in the other end 36 direction rather than the center portion between the one end 35 and the other end 36 of the plate-like radiating fin 10, and when the angle θ2 is smaller than the angle θ4, the twist start portion 41 is positioned in the one end 35 direction rather than the center portion between the one end 35 and the other end 36 of the plate-like radiating fin 10.

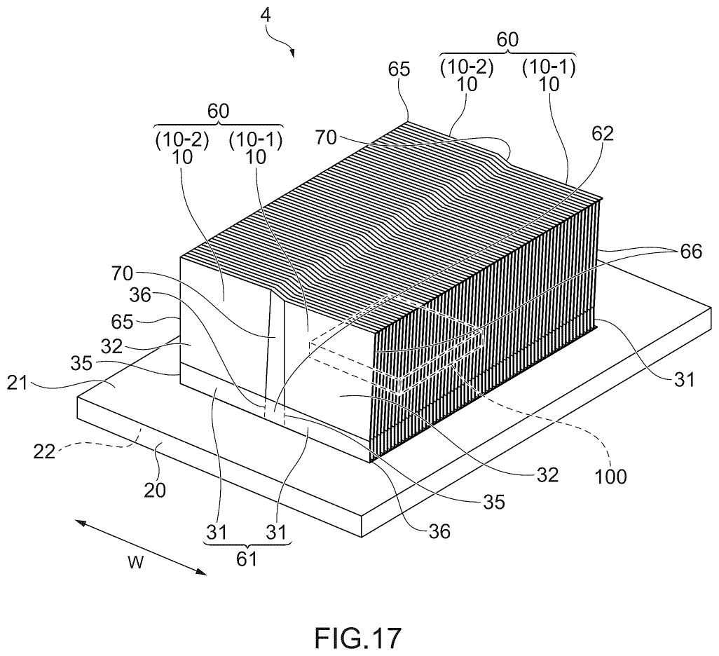

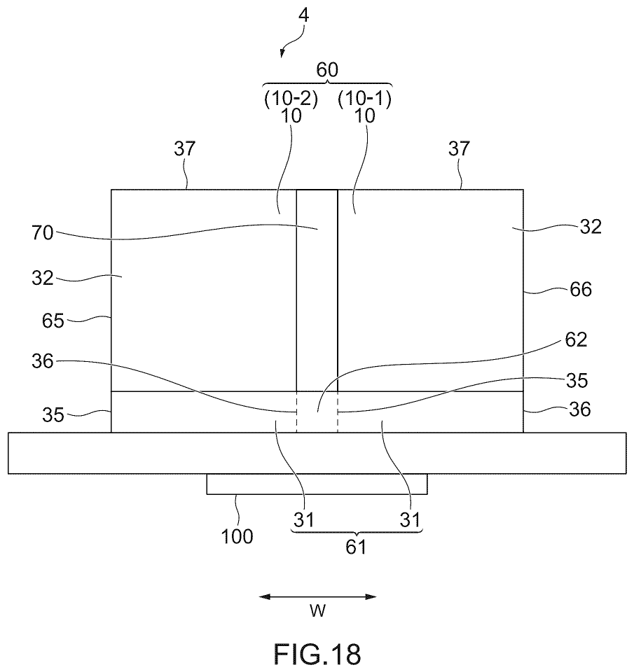

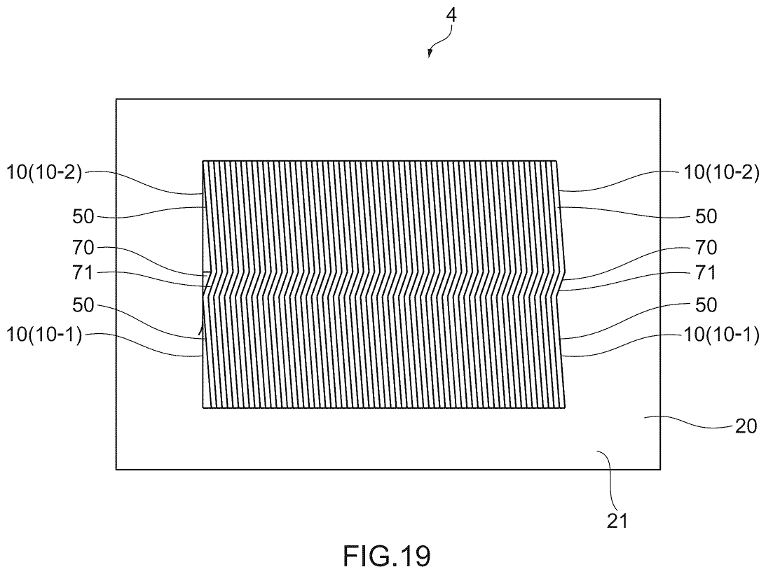

Next, a heat sink according to a fourth embodiment of the present disclosure will be described with reference to the accompanying drawings. The heat sink according to the fourth embodiment is in common with the heat sinks according to the first to third embodiments in terms of main components, and hence the same components as those of the heat sinks according to the first to third embodiments are described with use of the same reference characters. FIG. 17 is a perspective view of the heat sink according to the fourth embodiment of the present disclosure. FIG. 18 is a front view of the heat sink according to the fourth embodiment of the present disclosure. FIG. 19 is a plan view of the heat sink according to the fourth embodiment of the present disclosure.

In the heat sink 2 according to the second embodiment, the space between the twisted portion 32 of the plate-like radiating fin 10-1 of the integrated plate-like radiating fin 60 and the twisted portion 32 of the other adjacent plate-like radiating fin 10-2 is the gap 63. However, instead of this, as illustrated in FIGS. 17 and 18, in a heat sink 4 according to the fourth embodiment, a twisted portion 32 of a plate-like radiating fin 10-1 is connected to a twisted portion 32 of another adjacent plate-like radiating fin 10-2 via a joining portion 70. Accordingly, in the heat sink 4, the twisted portion 32 of the plate-like radiating fin 10-1 is integrated with the twisted portion 32 of the other adjacent plate-like radiating fin 10-2.

In the heat sink 4, as in the heat sink 2 according to the second embodiment, a plurality of plate-like radiating fins 10, 10, 10 . . . are also disposed along a width direction of a fin base portion 31 (that is, a width direction W of a plate-like radiating fin 10), an end portion in the width direction of the fin base portion 30 of the plate-like radiating fin 10 is connected to an end portion in a width direction of a fin base portion 31 of another adjacent plate-like radiating fin 10. As a result, the plurality of plate-like radiating fins 10, 10, 10 . . . are integrated, and an integrated plate-like radiating fin 60 is formed. From the above, the integrated plate-like radiating fin 60 has an integrated fin base portion 61 that is an aspect in which a plurality of fin base portions 31 of the plate-like radiating fins 10 are integrated. In the heat sink 4, the two plate-like radiating fins 10 are integrated, and thereby the integrated plate-like radiating fin 60 is formed.

As illustrated in FIGS. 17 and 18, in the integrated plate-like radiating fin 60, one end 35 in a width direction W of the plate-like radiating fin 10-1 in the fin base portion 31 is connected to another end 36 in the width direction W of the other adjacent plate-like radiating fin 10-2 in the fin base portion 31. As a result, the plurality of plate-like radiating fins 10 are integrated. In the fin base portion 31, the one end 35 in the width direction W of the plate-like radiating fin 10-1 is connected to the other end 36 in the width direction W of the other adjacent plate-like radiating fin 10-2 via a connecting portion 62. The one end 35 in the width direction W of the other plate-like radiating fin 10-2 is one end 65 of the integrated plate-like radiating fin 60, and the other end 36 in the width direction W of the plate-like radiating fin 10-1 is another end 66 of the integrated plate-like radiating fin 60.

As illustrated in FIG. 19, in the heat sink 4, a top surface portion 50 of the plate-like radiating fin 10-1 and a top surface portion 50 of the other plate-like radiating fin 10-2 are connected via a top surface portion 71 of the joining portion 70. Accordingly, the top surface portion 50 of the plate-like radiating fin 10-1 and the top surface portion 50 of the other plate-like radiating fin 10-2 are integrated. A bottom surface portion (not illustrated) of the plate-like radiating fin 10-1 and a bottom surface portion (not illustrated) of the other plate-like radiating fin 10-2 are also connected. The bottom surface portion of the plate-like radiating fin 10-1 and the bottom surface portion of the other plate-like radiating fin 10-2 are integrated, and an integrated bottom surface portion is formed.

In the integrated plate-like radiating fin 60 of the heat sink 4, the twisted portion 32 of the other plate-like radiating fin 10-2 of which extending direction differs from that of the integrated fin base portion 61 also guides cooling air in a direction from a fin tip 37 of the other plate-like radiating fin 10-2 to the fin base portion 31 (integrated fin base portion 61). The twisted portion 32 of which extending direction differs from that of the integrated fin base portion 61, of the plate-like radiating fin 10-1 positioned on the leeward of the other plate-like radiating fin 10-2 guides cooling air F in a direction from a fin tip 37 of the plate-like radiating fin 10-1 to the fin base portion 31 (integrated fin base portion 61).

In the heat sink 4, as a result of the fin base portions 31 of the plurality of plate-like radiating fins 10 being integrated, and the integrated plate-like radiating fin 60 being formed, a flow of the cooling air is a continuous flow at a high flow rate in the integrated fin base portion 61. Therefore, more excellent fin efficiency can also be obtained by further reducing a difference between a temperature of the fin base portion 31 and an average temperature of the plate-like radiating fin 10.

In the heat sink 4, the fin base portions 31 of the plurality of plate-like radiating fins 10 are integrated, and the twisted portion 32 of the plate-like radiating fin 10-1 is connected to the twisted portion 32 of the other plate-like radiating fin 10-2 via the joining portion 70. As a result, a surface area of the plate-like radiating fin 10 including the joining portion 70 increases to be able to contribute to improvement in a heat dissipation amount. The twisted portion 32 of the plate-like radiating fin 10-1 is connected to the twisted portion 32 of the other adjacent plate-like radiating fin 10-2 via the joining portion 70. As a result, noise generation when the cooling air flowing through the plate-like radiating fin 10 can be prevented in a more reliable manner.

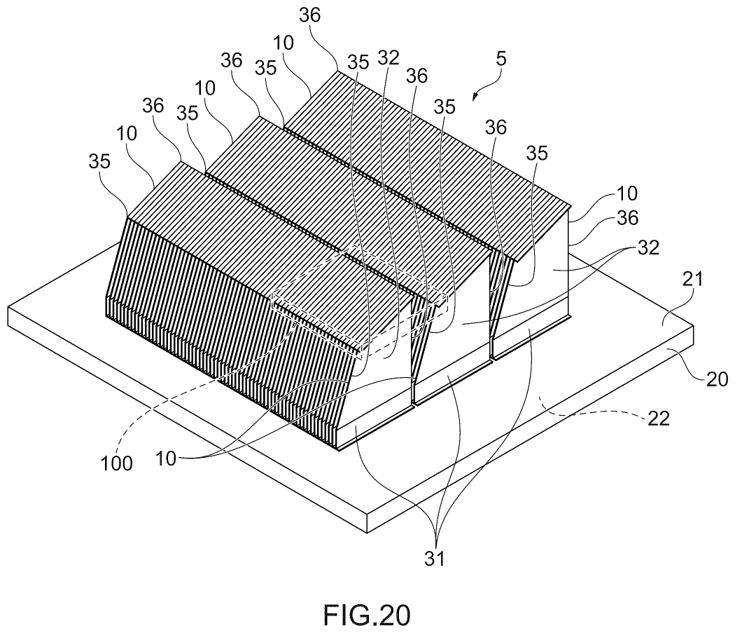

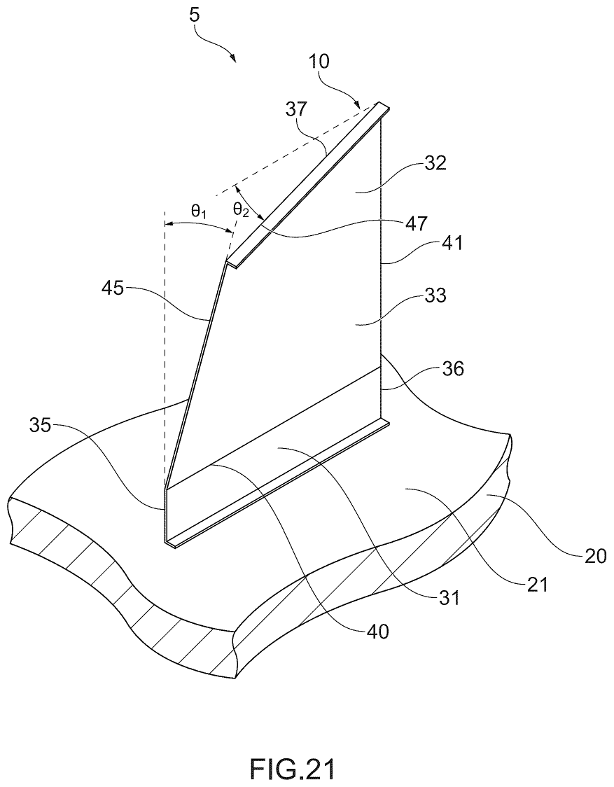

Next, a heat sink according to a fifth embodiment of the present disclosure will be described with reference to the accompanying drawings. The heat sink according to the fifth embodiment is in common with the heat sinks according to the first to fourth embodiments in terms of main components, and hence the same components as those of the heat sinks according to the first to fourth embodiments are described with use of the same reference characters. FIG. 20 is a perspective view of the heat sink according to the fifth embodiment of the present disclosure. FIG. 21 is a perspective view of a plate-like radiating fin included in the heat sink according to the fifth embodiment of the present disclosure.

In the heat sink 1 according to the first embodiment, the height of the plate-like radiating fin 10 is a substantially constant height from the one end 35 to the other end 36. However, instead of this, as illustrated in FIGS. 20 and 21, in a heat sink 5 according to the fifth embodiment, an aspect in which a height of one end 35 and a height of another end 36 of a plate-like radiating fin 10 are different is provided. In the heat sink 5, the aspect in which the other end 36 height of the plate-like radiating fin 10 is higher than the height of the one end 35 is provided. In the heat sink 5, the aspect in which a height increases from the one end 35 to the other end 36 of the plate-like radiating fin 10 is provided.

In the heat sink 5, as in the heat sink 1 according to the first embodiment, of a twisted portion 32, one end portion 45 inclines at a predetermined angle θ1 in a main front surface 21 direction of a base plate 20 with respect to a twist start portion 41 with a border 40 as a starting point, and the twist start portion 41 rectilinearly stretches in a perpendicular direction to an extending direction of a main front surface 21 of the base plate 20. A fin tip portion 47 of the twisted portion 32 inclines at a predetermined angle θ2 along the extending direction of the main front surface 21 of the base plate 20 from the twist start portion 41 to the one end portion 45 with respect to a stretching direction of the fin base portion 31, with the twist start portion 41 as a starting point.

In the heat sink 5, the fin base portion 31 also extends at a substantially constant height from the one end 35 to the other end 36 in a width direction of the plate-like radiating fin 10.

In the heat sink 5 in which the height of the one end 35 of the plate-like radiating fin 10 is different from the height of the other end 36, a flow of the cooling air is also guided to the fin base portion 31 of the plate-like radiating fin 10 by the twisted portion 32, and a flow rate of the cooling air in the fin base portion 31 also becomes higher than a flow rate of the cooling air in a fin tip 37. As a result, of the plate-like radiating fin 10, the flow rate of the cooling air in the fin base portion 31 that is the closest to the base plate 20 and is likely to have a highest temperature becomes high, and the flow rate of the cooling air in the fin tip 37 that is the farthest from the base plate 20 and least likely to have a high temperature is suppressed moderately. Therefore, a difference between the temperature of the fin base portion 31 and an average temperature of the entire plate-like radiating fin 10 is reduced, and hence the plate-like radiating fin 10 has excellent fin efficiency.

Furthermore, in the heat sink 5 in which the height of the one end 35 of the plate-like radiating fin 10 and the height of the other end 36 differ, a planar region 33 of the twisted portion 32 also extends from the twist start portion 41 to the one end portion 45 of the plate-like radiating fin 10, and from the border 40 with the fin base portion 31 to the fin tip portion 47. As a result, the cooling air supplied toward the other end 36 from the one end 35 of the plate-like radiating fin 10 also flows easily in a direction to the fin tip 37 and a vicinity of the fin tip 37 as the cooling air flows from the one end portion 45 to the twist start portion 41 while being guided to the fin base portion 31 of the plate-like radiating fin 10. As a result, in the heat sink 5, increase of pressure loss of the cooling air flowing through the plate-like radiating fin 10 can also be prevented. Therefore, the heat sink 5 can also exhibit excellent heat dissipation characteristics.

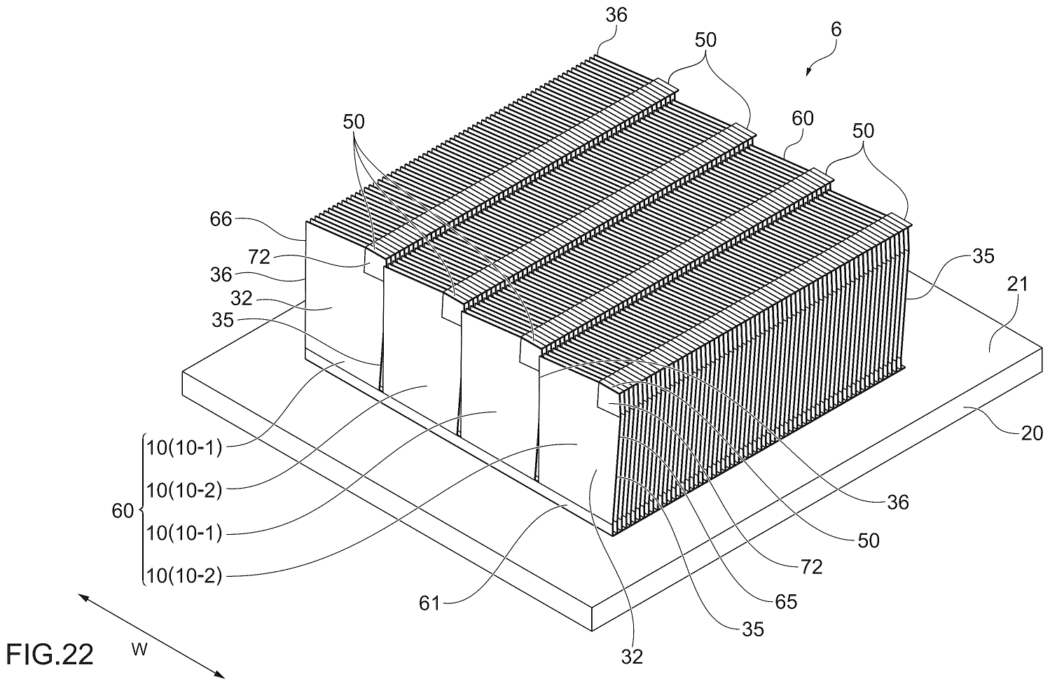

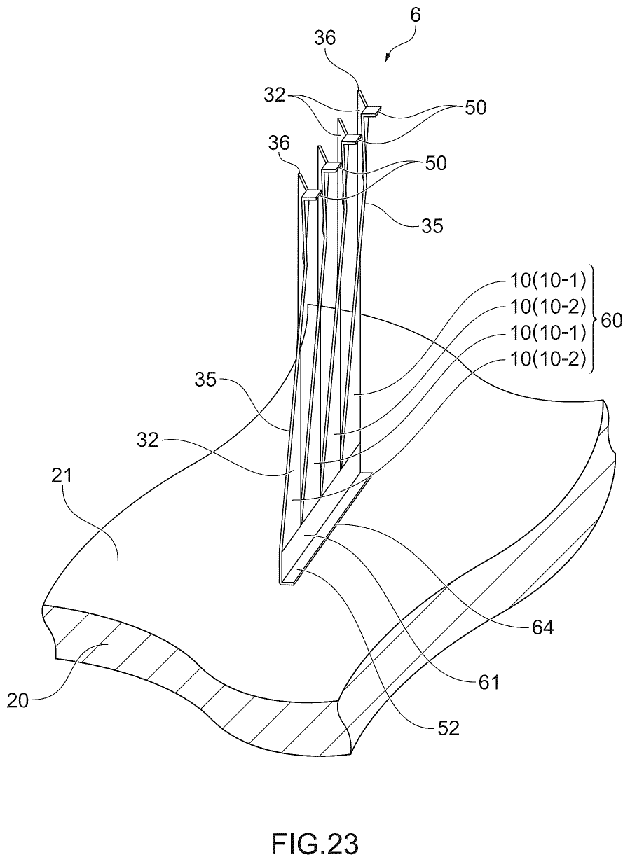

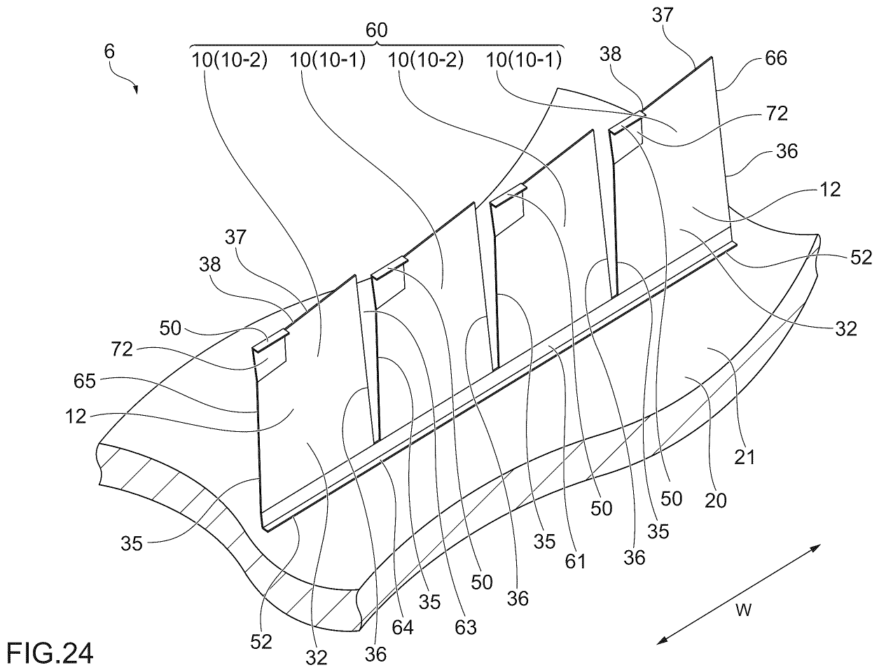

Next, a heat sink according to a sixth embodiment of the present disclosure will be described with reference to the accompanying drawings. The heat sink according to the sixth embodiment is in common with the heat sinks according to the first to fifth embodiments in terms of main components, and hence the same components as those of the heat sinks according to the first to fifth embodiments are described with use of the same reference characters. FIG. 22 is a perspective view of the heat sink according to the sixth embodiment of the present disclosure. FIG. 23 is a side view of a plate-like radiating fin included in the heat sink according to the sixth embodiment of the present disclosure. FIG. 24 is a perspective view of the plate-like radiating fin included in the heat sink according to the sixth embodiment of the present disclosure.

In the heat sink 2 according to the second embodiment, the top surface portion 50 of the plate-like radiating fin 10-1 is provided to the other end 36 from the one end 35 of the plate-like radiating fin 10-1, and the top surface portion 50 of the other plate-like radiating fin 10-2 is provided to the other end 36 from the one end 35 of the other plate-like radiating fin 10-2. However, instead of this, as illustrated in FIGS. 22 to 24, in a heat sink 6 according to the sixth embodiment, in an integrated plate-like radiating fin 60 formed by a plurality of plate-like radiating fins 10, 10, 10 . . . being integrated, a top surface portion 50 of a plate-like radiating fin 10-1 is provided only at one end 35 of the plate-like radiating fin 10-1, and a top surface portion 50 of another plate-like radiating fin 10-2 is provided only at one end 35 of the other plate-like radiating fin 10-2. In other words, in the heat sink 60, the top surface portion 50 of the plate-like radiating fin 10-1 is not provided at another end 36 of the plate-like radiating fin 10-1, and the top surface portion 50 of the other plate-like radiating fin 10-2 is not provided at another end 36 of the other plate-like radiating fin 10-2. In this way, in the heat sink of the present disclosure, the top surface portion 50 of the plate-like radiating fin 10 may be provided to the other end 36 from the one end 35 of the plate-like radiating fin 10, or may be provided at only a partial region (for example, the one end 35 or the other end 36 of the plate-like radiating fin 10) in a width direction W of the plate-like radiating fin 10.

In the heat sink 6, four plate-like radiating fins 10 are integrated, and an integrated plate-like radiating fin 60 is formed, for convenience of explanation. In the integrated plate-like radiating fin 60, two plate-like radiating fins 10-1 and two other plate-like radiating fins 10-2 are alternately disposed. In the heat sink 6, the top surface portion 50 of the plate-like radiating fin 10-1 and the top surface portion 50 of the other plate-like radiating fin 10-2 are not connected, either. Therefore, the top surface portion 50 of the plate-like radiating fin 10-1 and the top surface portion 50 of the other plate-like radiating fin 10-2 are separate bodies. Meanwhile, in the heat sink 6, a bottom surface portion 52 of the plate-like radiating fin 10-1 and a bottom surface portion 52 of the other plate-like radiating fin 10-2 are also connected. The bottom surface portion 52 of the plate-like radiating fin 10-1 and the bottom surface portion 52 of the plate-like radiating fin 10-2 are integrated, and an integrated bottom surface portion 64 is formed.

As illustrated in FIGS. 23 and 24, in the heat sink 6, an extending direction of the top surface portion 50 of the plate-like radiating fin 10-1 is a substantially same direction as and substantially parallel direction to an extending direction of the integrated bottom surface portion 64. The top surface portion 50 of the other plate-like radiating fin 10-2 is also a substantially same direction as and a substantially a parallel direction to the extending direction of the integrated bottom surface portion 64. The top surface portion 50 of the plate-like radiating fin 10-1 extends in a perpendicular direction to a planar surface portion of an integrated fin base portion 61. The top surface portion 50 of the other plate-like radiating fin 10-2 also extends in a perpendicular direction to the planar surface portion of the integrated fin base portion 61. Therefore, of a main front surface 12 of the plate-like radiating fin 10-1, a corner portion region 72 in a vicinity of the top surface portion 50 is not a twisted portion 32, but is a section positioned on a substantially same planar surface as the planar surface portion of the integrated fin base portion 61. From the above, in the plate-like radiating fin 10-1 of the heat sink 6, a fin tip 37 has a bent portion 38 in the width direction W of the plate-like radiating fin 10-1 in a vicinity of the one end 35. Of a main front surface 12 of the other plate-like radiating fin 10-2, a corner portion region 72 in a vicinity of the top surface portion 50 is not a twisted portion 32, but is a section positioned on a substantially same planar surface as a planar surface portion of the integrated fin base portion 61. From the above, in the other plate-like radiating fin 10-2 of the heat sink 6, a fin tip 37 has a bent portion 38 in a width direction W of the other plate-like radiating fin 10-2, in a vicinity of the one end 35.

As illustrated in FIG. 22, in the heat sink 6, in the width direction W of the plate-like radiating fin 10, a plurality of integrated plate-like radiating fins 60, 60, 60 . . . are parallelly disposed on the base plate 20 to be on a substantially straight line, in a direction substantially orthogonal to the width direction W of the plate-like radiating fin 10.

In the heat sink 6, cooling air supplied from a blower fan (not illustrated) to the heat sink 6 is supplied to flow in a direction to another end 66 of the integrated plate-like radiating fin 60, that is, the other end 36 of the plate-like radiating fin 10-1 from one end 65 of the integrated plate-like radiating fin 60, that is, the one end 35 of the other plate-like radiating fin 10-2. From the above, the cooling air is supplied toward the other end 66 from the one end 65, in a width direction W of the integrated plate-like radiating fin 60. As a result of the cooling air being supplied to the heat sink 6, the heat sink 6 can exhibit excellent cooling performance. The cooling air supplied to the heat sink 6 cools the heat sink 6 by flowing along a main front surface 12 of the other plate-like radiating fin 10-2 and a main front surface 12 of the plate-like radiating fin 10-1, in an extending direction of a main front surface 21 of the base plate 20.

In the integrated plate-like radiating fin 60 of the heat sink 6, the twisted portion 32 of the other plate-like radiating fin 10-2 of which extending direction differs from that of the integrated fin base portion 61 also guides the cooling air in a direction to the integrated fin base portion 61 from the fin tip 37 of the other plate-like radiating fin 10-2. In the integrated plate-like radiating fin 60, even when a flow of the cooling air in the direction to the fin tip 37 from the integrated fin base portion 61 is formed by a gap 63 between the twisted portion 32 of the other plate-like radiating fin 10-2 and the twisted portion 32 of the plate-like radiating fin 10-1, the twisted portion 32 of which extending direction differs from that of the integrated fin base portion 61, of the plate-like radiating fin 10-1 positioned on the leeward side of the other plate-like radiating fin 10-2 guides the cooling air in the direction to the integrated fin base portion 61 from the fin tip 37 of the plate-like radiating fin 10-1.

In the heat sink 6, as a result of the integrated plate-like radiating fin 60 being formed, the flow of the cooling air also becomes a continuous flow at a high flow rate in the integrated fin base portion 61. Therefore, a difference between a temperature of the integrated plate-like radiating fin 60 and an average temperature of the plate-like radiating fin 10 can be further reduced, and more excellent fan efficiency can be obtained.

In the heat sink 6, a space between the twisted portion 32 of the plate-like radiating fin 10-1 and the twisted portion 32 of the other adjacent plate-like radiating fin 10-2 is the gap 63. As a result, the cooling air flows through the gap 63 even when the plurality of plate-like radiating fins 10, 10, 10 . . . are integrated, and hence increase of pressure loss of the cooling air can be reliably prevented.

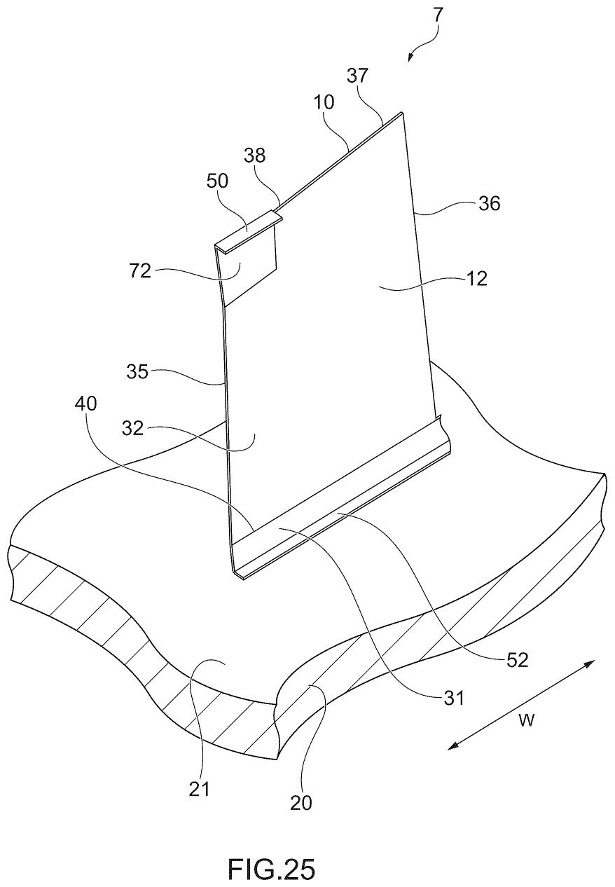

Next, a heat sink according to a seventh embodiment of the present disclosure will be described with reference to the accompanying drawings. The heat sink according to the seventh embodiment is in common with the heat sinks according to the first to sixth embodiments in terms of main components, and hence the same components as those of the heat sinks according to the first to sixth embodiments are described with use of the same reference characters. FIG. 25 is a perspective view of a plate-like radiating fin included in the heat sink according to the seventh embodiment of the present disclosure.

In the heat sink 1 according to the first embodiment, the top surface portion 50 of the plate-like radiating fin 10 is provided from the one end 35 to the other end 36 of the plate-like radiating fin 10. However, Instead of this, as illustrated in FIG. 25, in a heat sink 7 according to the seventh embodiment, a top surface portion 50 of a plate-like radiating fin 10 is provided at only one end 35 of the plate-like radiating fin 10. In other words, in the heat sink 7, the top surface portion 50 of the plate-like radiating fin 10 is not provided at another end 36 of the plate-like radiating fin 10.

As illustrated in FIG. 24, in the heat sink 7, an extending direction of the top surface portion 50 of the plate-like radiating fin 10 is a substantially same direction as and a substantially parallel direction to an extending direction of a bottom surface portion 52. The top surface portion 50 of the plate-like radiating fin 10 extends in a perpendicular direction to a fin base portion 31 that is a planar surface portion. Therefore, of a main front surface 12 of the plate-like radiating fin 10, a corner portion region 72 in a vicinity of the top surface portion 50 is not the twisted portion 32, but is a section positioned on a substantially same planar surface as the fin base portion 31. From the above, in the plate-like radiating fin 10 of the heat sink 7, a fin tip 37 has a bent portion 38 in a width direction W of the plate-like radiating fin 10, in a vicinity of the one end 35.

In the heat sink 7, a flow of cooling air is guided to the fin base portion 31 of the plate-like radiating fin 10 by the twisted portion 32, and a flow rate of the cooling air in the fin base portion 31 becomes faster than a flow rate of the cooling air in the fin tip 37. As a result, of the plate-like radiating fin 10, the flow rate of the cooling air in the fin base portion 31 closest to the base plate 20 and being likely to have a highest temperature becomes fast, and the flow rate of the cooling air in the fin tip 37 farthest from the base plate 20 and least likely to have the highest temperature is suppressed moderately. Therefore, a difference between the temperature of the fin base portion 31 and an average temperature of the entire plate-like radiating fin 10 is reduced, and hence the plate-like radiating fin 10 has excellent fin efficiency.

Furthermore, in the heat sink 7, the cooling air supplied toward the other end 36 from the one end 35 of the plate-like radiating fin 10 also flows easily in a direction to the fin tip 37 and a vicinity of the fin tip 37 while being guided to the fin base portion 31 of the plate-like radiating fin 10, by the twisted portion 32. As a result, in the heat sink 7, increase of pressure loss of the cooling air flowing through the plate-like radiating fin 10 can be prevented. Therefore, in the heat sink 7, excellent heat dissipation characteristics can be exhibited.

Next, other embodiments of the heat sink of the present disclosure will be described.

In the heat sink according to each of the above-described embodiments, the fin base portion extends planarly to the other end from the one end of the plate-like radiating fin in the width direction of the plate-like radiating fin. However, instead of this, the fin base portion may linearly extend to the other end from the one end of the plate-like radiating fin in the width direction of the plate-like radiating fin.

In the heat sink according to the third embodiment, the inclining direction of the angle θ1 of the one end portion with respect to the twist start portion in the first planar region is opposite to the inclining direction of the angle θ3 of the other end portion with respect to the twist start portion in the second planar region, and the inclining direction of the angle θ2 of the first fin tip portion with respect to the stretching direction of the fin base portion in the first planar region is opposite to the inclining direction of the angle θ4 of the second fin tip portion with respect to the stretching direction of the fin base portion in the second planar region. However, instead of this, the inclining direction of the angle θ1 with respect to the twist start portion in the first planar region may be the same as the inclining direction of the angle θ3 with respect to the twist start portion in the second planar region, and the inclining direction of the angle θ2 with respect to the stretching direction of the fin base portion in the first planar region may be the same as the inclining direction of the angle θ4 with respect to the stretching direction of the fin base portion in the second planar region.

According to the above-described aspect, in both the first planar region and the second planar region, a flow of the cooling air is guided to the fin base portion of the plate-like radiating fin and a flow rate of the cooling air in the fin base portion becomes a high flow rate, and hence a difference between a temperature of the fin base portion and an average temperature of the radiating fin can be further reduced.

In the heat sink according to the third embodiment, the twist start portion is positioned between the one end and the other end of the plate-like radiating fin, and the twisted portion of the plate-like radiating fin has the first planar region and the second planar region with the twist start portion as the border, as the planar regions. However, instead of this, the twist start portion is positioned between the one end and the other end of the plate-like radiating fin, and the second planar region may not form the twisted portion. In other words, the second planar region may be defined by the border with the fin base portion, the twist start portion, the other end portion that faces the twist start portion, and does not incline in the direction to the main front surface of the base plate with respect to the twist start portion (substantially parallel to the twist start portion), and the second fin tip portion that is a part of the fin tip facing the fin base portion, and does not incline along the extending direction of the main front surface of the base plate toward the other end portion from the twist start portion with respect to the stretching direction of the fin base portion (substantially parallel to the fin base portion).

In the heat sink of the present disclosure, excellent fin efficiency is obtainable by reducing the difference between the temperature of the fin base portion and the average temperature of the radiating fin, and the increase of the pressure loss of the cooling air can be prevented as a result of the cooling air also flowing easily in the fin tip and the vicinity of the fin tip, in an environment in which the installation space of the heat sink is limited. Therefore, for example, the heat sink of the present disclosure has high utility value in a field of cooling electronic components with high heat generation amount installed on a circuit substrate installed in a narrow space, for example, electronic components of a central processing unit and the like.

What is claimed is:

1. A heat sink comprising:
a base plate thermally connected to a heat-generating element; and
a plurality of radiating fins erected on a main front surface of the base plate and thermally connected to the base plate,
wherein the radiating fins each having a width direction and a height direction each including:
a fin base portion that extends from one end to another end in the width direction of the radiating fin along the main front surface of the base plate; and
a twisted portion that is continuously provided in the height direction of the radiating fin from the fin base portion, and inclines in a main front surface direction of the base plate, and
the twisted portion has a planar region defined by,
a twist start portion that linearly stretches from the fin base portion along the height direction of the radiating fin,
one end portion that is at least a part of the one end facing the twist start portion, and inclines at an angle θ1 in the main front surface direction of the base plate with respect to the twist start portion, and
a fin tip portion that is at least a part of a fin tip facing the fin base portion, and inclines at an angle θ2 along an extending direction of the main front surface of the base plate to the one end portion from the twist start portion, with respect to a stretching direction of the fin base portion.

2. The heat sink according to claim 1, wherein the twist start portion is positioned at the other end.

3. The heat sink according to claim 2, wherein the fin base portion has a planar surface portion extending from the one end to the other end in the width direction of the radiating fin.

4. The heat sink according to claim 1, wherein the twist start portion is positioned between the one end and the other end.

5. The heat sink according to claim 4, wherein the fin base portion has a planar surface portion extending from the one end to the other end in the width direction of the radiating fin.

6. The heat sink according to claim 4, wherein the twisted portion has
a first planar region defined by,
the one end portion that is at least a part of the one end facing the twist start portion, and inclines at an angle θ1 in the main front surface direction of the base plate with respect to the twist start portion, and
a first fin tip portion that is a part of the fin tip facing the fin base portion, and inclines at an angle θ2 along the extending direction of the main front surface of the base plate to the one end portion from the twist start portion, with respect to the stretching direction of the fin base portion, and
a second planar region defined by
another end portion that is at least a part of the other end facing the twist start portion, and inclines at an angle θ3 in the main front surface direction of the base plate with respect to the twist start portion, and
a second fin tip portion that is a part of the fin tip facing the fin base portion, and inclines at an angle θ4 along the extending direction of the main front surface of the base plate to the other end portion from the twist start portion with respect to the stretching direction of the fin base portion.

7. The heat sink according to claim 6, wherein an inclining direction of the angle θ1 with respect to the twist start portion is opposite to an inclining direction of the angle θ3 with respect to the twist start portion, and an inclining direction of the angle θ2 with respect to the stretching direction of the fin base portion is opposite to an inclining direction of the angle θ4 with respect to the stretching direction of the fin base portion.

8. The heat sink according to claim 6, wherein an inclining direction of the angle θ1 with respect to the twist start portion is the same as an inclining direction of the angle θ3 with respect to the twist start portion, and an inclining direction of the angle θ2 with respect to the stretching direction of the fin base portion is the same as an inclining direction of the angle θ4 with respect to the stretching direction of the fin base portion.

9. The heat sink according to claim 6, wherein the angle θ1 is 2.0 degrees or more and 20 degrees or less, and the angle θ3 is 2.0 degrees or more and 20 degrees or less.

10. The heat sink according to claim 6, wherein the angle θ2 is 2.0 degrees or more and 20 degrees or less, and the angle θ4 is 2.0 degrees or more and 20 degrees or less.

11. The heat sink according to claim 1, wherein as a result of a plurality of the radiating fins being disposed along a width direction of the fin base portion, and an end portion in the width direction of the fin base portion of the radiating fin being connected to an end portion in a width direction of the fin base portion of another adjacent one of the radiating fins, the plurality of the radiating fins are integrated.

12. The heat sink according to claim 11, wherein a space between the twisted portion of the radiating fin and the twisted portion of the other adjacent radiating fin is a gap.

13. The heat sink according to claim 11, wherein the twisted portion of the radiating fin is connected to the twisted portion of the other adjacent radiating fin via a joining portion.

14. The heat sink according to claim 1, wherein the fin base portion has a planar surface portion extending from the one end to the other end in the width direction of the radiating fin.

15. The heat sink according to claim 1, wherein a top surface portion having a planar surface shape further extends from the fin tip.

16. The heat sink according to claim 15, wherein a top surface is formed on a radiating fin group formed by the plurality of radiating fins as a result of the top surface portion abutting against the fin tip of another adjacent one of the radiating fins.

17. The heat sink according to claim 1, wherein a bottom surface portion having a planar surface shape further extends from a bottom portion of the fin base portion along the extending direction of the main front surface of the base plate.

18. The heat sink according to claim 17, wherein a bottom surface is formed on a radiating fin group formed by the plurality of radiating fins as a result of the bottom surface portion abutting against the fin base portion of another adjacent one of the radiating fins.

19. The heat sink according to claim 1, wherein a height of the fin base portion with respect to a height of the radiating fin is 30% or less.

20. The heat sink according to claim 1, wherein the angle θ1 is 2.0 degrees or more and 20 degrees or less.

21. The heat sink according to claim 1, wherein the angle θ2 is 2.0 degrees or more and 20 degrees or less.

22. The heat sink according to claim 1, wherein cooling air is supplied from the one end toward the other end, in the width direction of the plate-like radiating fin.
